(19) United States
(12) Patent Application Publication
(10) Pub. No.: US 2026/0096454 A1
(43) Pub. Date: Apr. 2, 2026

(54) TECHNOLOGIES FOR THROUGH-GLASS VIAS WITH CAPS

(71) Applicant: Intel Corporation, Santa Clara, CA (US)

(72) Inventors: Manohar Konchady, Chandler, AZ (US); Srinivas Venkata Ramanuja Pietambaram, Chandler, AZ (US); Nirupama Chakrapani, Chandler, AZ (US); Jason Michael Gamba, Gilbert, AZ (US); Tarek A. Ibrahim, Mesa, AZ (US); Mohammad Mamunur Rahman, Gilbert, AZ (US)

(73) Assignee: Intel Corporation, Santa Clara, CA (US)

(21) Appl. No.: 18/900,178

(22) Filed: Sep. 27, 2024

(51) Int. Cl. H01L 23/498; H01L 21/768; H01L 23/08

(52) U.S. Cl. CPC H10W 70/635; H10W 20/043; H10W 76/18

(57) ABSTRACT

Technologies for through-glass vias with caps are disclosed. In an illustrative embodiment, a substrate core has holes defined in it, and vias are positioned in the holes to carry power or data signals through the substrate core. The vias are formed using bottom-up plating, forming vias that are not anchored to the sidewalls of the holes in the substrate core. The vias can thus move relative to the substrate core, which can mitigate cracking of the core during thermal cycling. In order to mitigate cracking in the build-up layers on the core, the via has a via cap, which can reduce the stress in the build-up layers. Various configurations of such vias are disclosed, and various approaches to fabricate such vias are disclosed.

### BACKGROUND

Glass cores for circuit boards and other electronic components are becoming more common. In order to transport power and data signals through the glass cores, through-glass vias (TGVs) can be formed in the glass cores. The vias may be made of copper or other conductive material. However, the coefficient of thermal expansion (CTE) of the glass core and the vias may be mismatched, causing stress when subject to thermal cycling. In some cases, the stress can cause cracks in the glass cores.

### BRIEF DESCRIPTION OF THE DRAWINGS

FIG. 1 is an isometric view of one embodiment of a system with an integrated circuit component on a circuit board with a substrate core.

FIG. 2 is a cross-sectional view of one embodiment of the system of FIG. 1.

FIG. 3 is a cross-sectional view of one embodiment of the system of FIG. 1.

FIG. 4 is a cross-sectional view of one embodiment of the system of FIG. 1.

FIG. 5 is a cross-sectional view of one embodiment of the system of FIG. 1.

FIG. 6 is a flowchart of one embodiment of a method of creating one embodiment of the system of FIG. 1.

FIG. 7 is a cross-sectional view of one embodiment of a glass core at one stage of the flowchart of FIG. 6.

FIG. 8 is a cross-sectional view of one embodiment of a glass core at one stage of the flowchart of FIG. 6.

FIG. 9 is a cross-sectional view of one embodiment of a glass core at one stage of the flowchart of FIG. 6.

FIG. 10 is a cross-sectional view of one embodiment of a glass core at one stage of the flowchart of FIG. 6.

FIG. 11 is a cross-sectional view of one embodiment of a glass core at one stage of the flowchart of FIG. 6.

FIG. 12 is a cross-sectional view of one embodiment of a glass core at one stage of the flowchart of FIG. 6.

FIG. 13 is a cross-sectional view of one embodiment of a glass core at one stage of the flowchart of FIG. 6.

FIG. 14 is a cross-sectional view of one embodiment of a glass core at one stage of the flowchart of FIG. 6.

FIG. 15 is a flowchart of one embodiment of a method of creating one embodiment of the system of FIG. 1.

FIG. 16 is a cross-sectional view of one embodiment of a glass core at one stage of the flowchart of FIG. 15.

FIG. 17 is a cross-sectional view of one embodiment of a glass core at one stage of the flowchart of FIG. 15.

FIG. 18 is a cross-sectional view of one embodiment of a glass core at one stage of the flowchart of FIG. 15.

FIG. 19 is a cross-sectional view of one embodiment of a glass core at one stage of the flowchart of FIG. 15.

FIG. 20 is a flowchart of one embodiment of a method of creating one embodiment of the system of FIG. 1.

FIG. 21 is a cross-sectional view of one embodiment of a glass core at one stage of the flowchart of FIG. 20.

FIG. 22 is a cross-sectional view of one embodiment of a glass core at one stage of the flowchart of FIG. 20.

FIG. 23 is a cross-sectional view of one embodiment of a glass core at one stage of the flowchart of FIG. 20.

FIG. 24 is a cross-sectional view of one embodiment of a glass core at one stage of the flowchart of FIG. 20.

FIG. 25 is a cross-sectional view of one embodiment of a glass core at one stage of the flowchart of FIG. 20.

FIG. 26 is a cross-sectional view of one embodiment of a glass core at one stage of the flowchart of FIG. 20.

FIG. 27 is a cross-sectional view of one embodiment of a glass core at one stage of the flowchart of FIG. 20.

FIG. 28 is a top view of a wafer and dies that may be included in a microelectronic assembly, in accordance with any of the embodiments disclosed herein.

FIG. 29 is a cross-sectional side view of an integrated circuit device that may be included in a microelectronic assembly, in accordance with any of the embodiments disclosed herein.

FIGS. 30A-30D are perspective views of example planar, gate-all-around, and stacked gate-all-around transistors.

FIG. 31 is a cross-sectional side view of an integrated circuit device assembly that may include a microelectronic assembly, in accordance with any of the embodiments disclosed herein.

FIG. 32 is a block diagram of an example electrical device that may include a microelectronic assembly, in accordance with any of the embodiments disclosed herein.

### DETAILED DESCRIPTION

In various embodiments disclosed herein, an integrated circuit component has a circuit board with a semiconductor die disposed on its surface. The circuit board has a substrate core with a vias defined in it. In an illustrative embodiment, the vias are not anchored to the sidewalls, which can mitigate cracking of the core due to thermal cycling and mismatch of coefficient of thermal expansion between the via material and the core material. The vias also include a cap or pad, which can also mitigate cracking of the dielectric layers built up on the substrate core.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

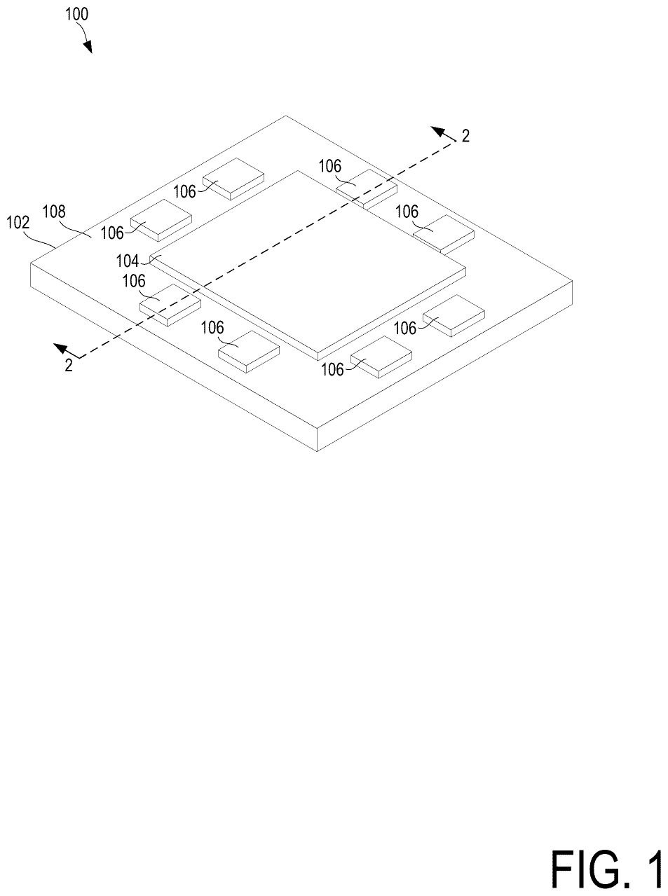

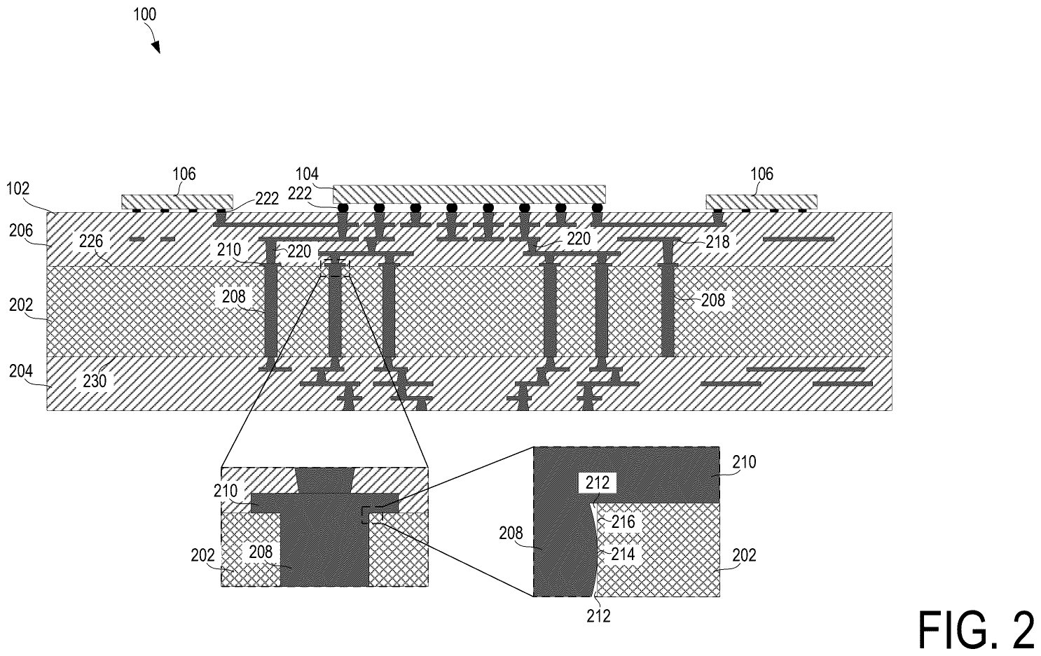

Referring now to FIGS. 1 and 2, in one embodiment, an integrated circuit component 100 includes a circuit board 102 on which one or more dies 104 are mounted. FIG. 1 shows an isometric view of the integrated circuit component 100, and FIG. 2 shows a cross-sectional view of the integrated circuit component 100. As shown in FIG. 1, a die 104 such as a processor die 104 may be disposed on the top surface 108 of the circuit board 102. In an illustrative embodiment, additional components, such as other semiconductor dies 106 (such as memory dies, other processor dies, etc.), are disposed on the top surface 108 of the circuit board 102 as well.

It should be appreciated that, as used herein, the “top side,” “bottom side,” etc., is an arbitrary designation used for clarity and does not denote a particular required orientation for manufacture or use. Although the illustrative embodiment described has the dies 104, 106 placed on the “top” side of the circuit board 102, in some embodiments, those components may be placed on the “bottom” side of the circuit board 102.

The circuit board 102 includes a substrate core 202, lower build-up layers 204, and upper build-up layers 206. Holes or cavities are defined in the substrate core 202 that extend from the top surface 226 of the substrate core 202 to the bottom surface 230 of the substrate core 202. Vias 208 are disposed in the holes. As discussed in more detail below, in an illustrative embodiment, the vias 208 are fabricated in a manner that does not anchor them to the sidewalls 216 of the holes. As a result, there may be a gap 212 between the vias 208 and the sidewalls 216 of the holes. The gap 212 may be, e.g., 5-200 nanometers, with an average gap 212 of, e.g., 10-150 nanometers. Of course, there may be some contact points 214 over a relatively small area between the vias 208 and the sidewalls 216, as shown in the inset of FIG. 2. However, more of the surface area of the via 208 is not in contact with the sidewalls 216. For example, a cross-section taken perpendicular to a via 208 may show that the via 208 is not touching the sidewalls 216 at all at that cross-section. In general, less than half (e.g., 50%-1% or even less) of the surface area of the via 208 will be in contact with the sidewalls 216. Because the vias 208 are not anchored to the sidewalls 216, when the integrated circuit component 100 is thermally cycled, the vias 208 can expand and contract due to elastic deformation independently of the substrate core 202, which can mitigate cracking in the substrate core 202. However, the vias 208 may still expand more than the substrate core 202, putting stress on the dielectric build-up layers 204, 206. In particular, the stress can be greatest where the via 208, the substrate core 202, and the build-up layers 204, 206 would meet (without the via caps 210).

In order to mitigate the stress in the build-up layers 204, 206, via caps 210 are formed at one or both ends of the via 208. The via caps 210 may also be referred to as pads or via pads. The via caps 210 can reduce the stress in the build-up layers 204, 206. In some embodiments, the via caps 210 may be anchored to part of the substrate core 202, such as the top surface 226 of the substrate core 202. In other embodiments, a via cap 210 may not be anchored to any part of the substrate core 202. Different manufacturing approaches that can lead to anchored via caps 210 or unanchored via caps 210 are described in more detail below.

In an illustrative embodiment, the circuit board 102 is a multi-layer circuit board 102 with build-up layers 204, 206 above and below the substrate core 202. The build-up layers 204, 206 may have any suitable number of layers, such as 1-10 layers each. In other embodiments, the circuit board 102 may be a single-layer circuit board 102. In an illustrative embodiment, the substrate core 202 is an inorganic core, such as a glass core. The glass core may be silicon oxide glass. In other embodiments, the glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight. In other embodiments, the substrate core 202 may be an organic core, such as a fiberglass board made of glass fibers and a resin, such as FR-4.

The thickness of the circuit board 102 may be any suitable thickness, such as 100 micrometers to 5 millimeters. The thickness of the substrate core 202 may be any suitable thickness, such as 50 micrometers to 2 millimeters. The circuit board 102 can have any suitable length and width, such as 1-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 is planar. In other embodiments, the circuit board 102 may be non-planar.

In an illustrative embodiment, the die 104 is a processor die, and other dies 106 may be memory dies communicatively coupled to the processor die 104. In other embodiments, the die 104 and/or the dies 106 may be any suitable die, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104, 106 may be connected to contact pads or vias 220 on the circuit board 102 through conductive contacts 222, such as solder balls.

The vias 208 in the core 202 may transport power and/or data signals through the substrate core 202. In an illustrative embodiment, the vias 208 are made of copper. In other embodiments, the vias 208 may be made of any suitable conductive material, such as tungsten, polysilicon, etc. The core 202 may have any suitable number of vias 208 extending through it, such as 1-10,000 vias 208. The vias 208 may have any suitable diameter, such as 10-500 micrometers. The vias 208 may be connected to other traces 218, vias 220, etc., on the build-up layers 204, 206 to connect to various components on the top surface or bottom surface of the circuit board 102. The traces 218 and vias 220 may be made of any suitable conductive material, such as copper or aluminum.

The build-up layers 204, 206 may be made of any suitable material or materials, such as any suitable dielectric that can support the traces 218, vias 220, etc. In an illustrative embodiment, the build-up layers 204, 206 may be made of a resin material filled with a filler, such as Ajinomoto build-up film (ABF).

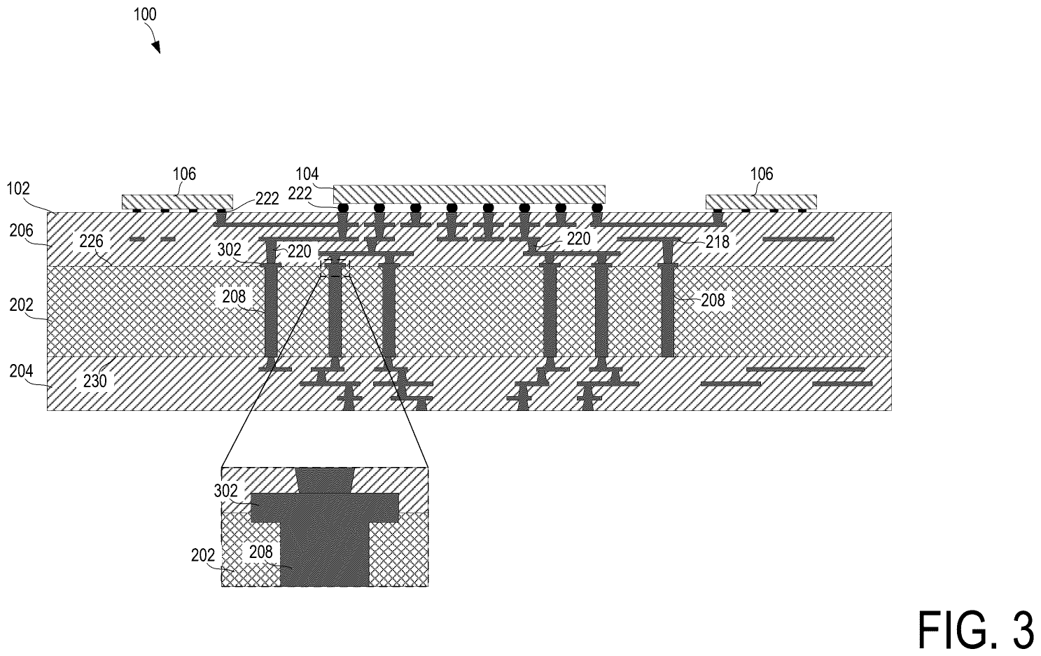

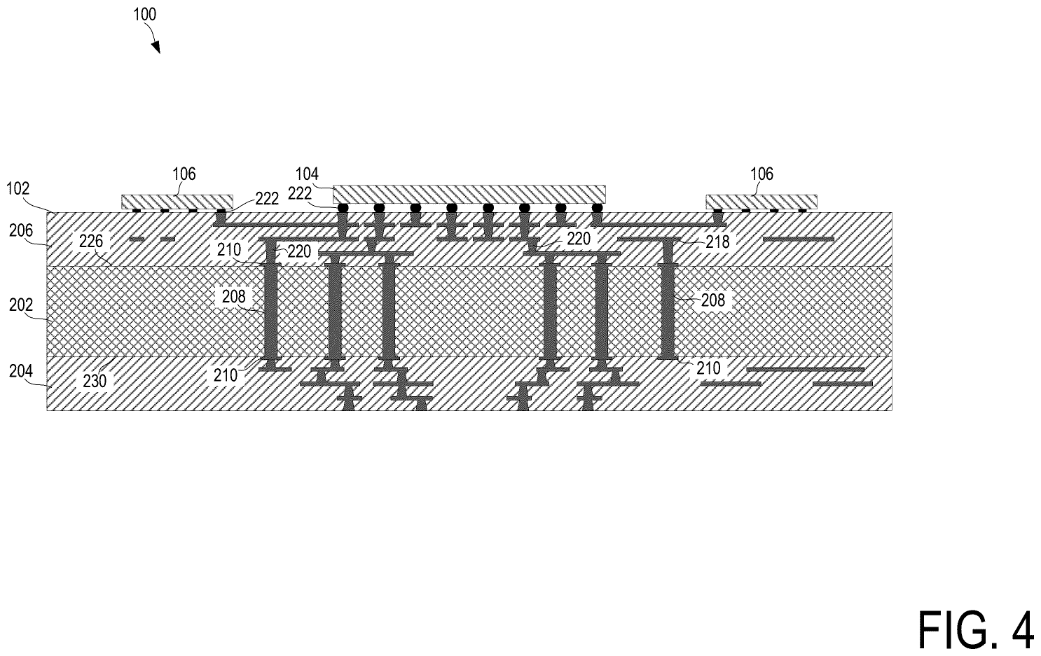

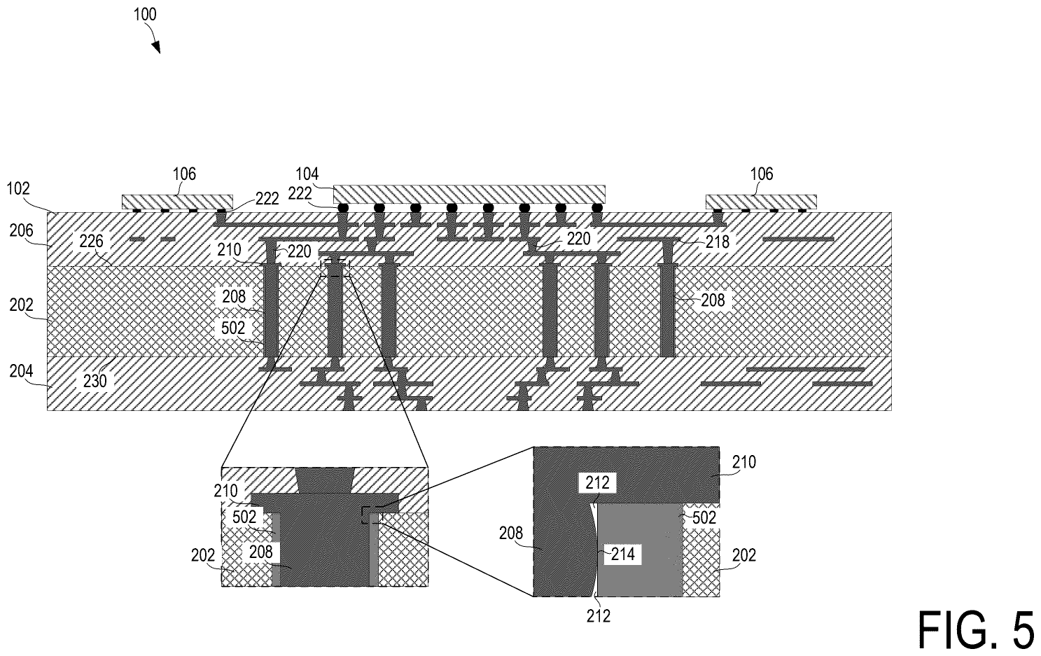

A range of variations of the vias 208 and via caps 210 described above are envisioned as well. For example, in one embodiment, the via caps 302 may be countersunk into the core 202, as shown in FIG. 3. The countersunk via caps 302 may further improve stress mitigation. In the embodiment shown in FIG. 2, the vias 208 only have via caps 210 on the top end of the vias 208, at the interface with the top build-up layer 206. Additionally or alternatively, in some embodiments, vias 208 may have via caps 210 on the bottom end of the vias, at the interface with the bottom build-up layer 206, as shown in FIG. 4. In some embodiments, a liner 502 may be present between the vias 208 and the core 202, as shown in FIG. 5. The liner 502 may be any suitable material, such as a polymer. The via caps 210 may have any suitable dimensions, such as a diameter of 20-1,000 micrometers and a thickness of 5-35 micrometers.

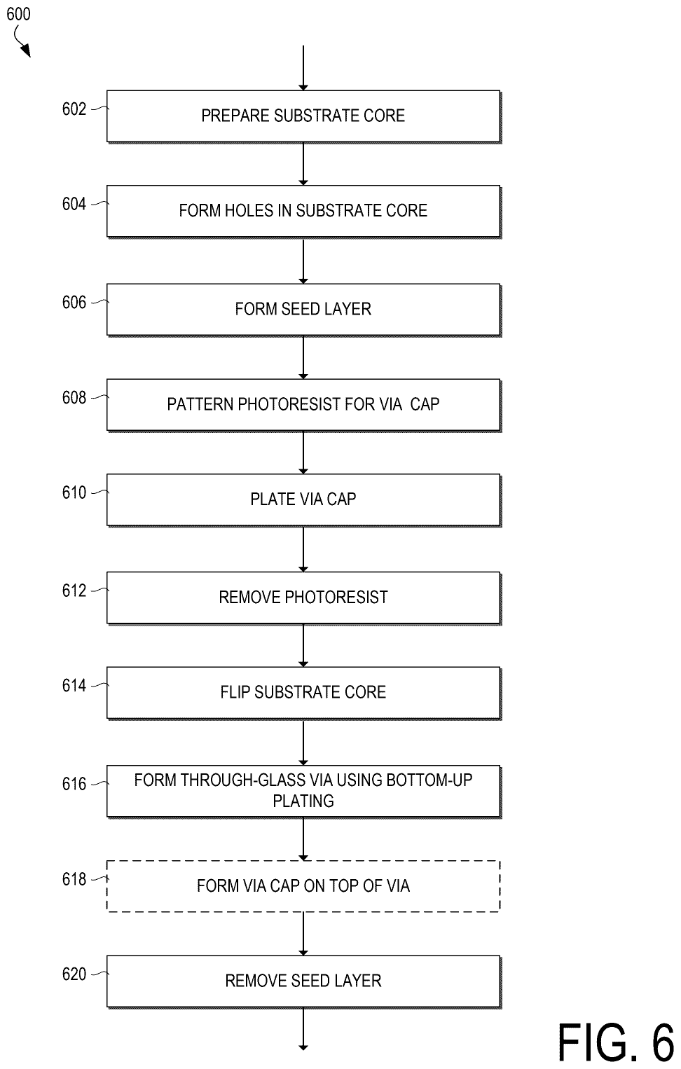

Referring now to FIG. 6, in one embodiment, a flowchart for a method 600 for creating the integrated circuit component 100 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, cause the machine to perform some or all of the steps of the method 600. The method 600 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 600 is merely one embodiment of a method to create one embodiment of a system, and other methods may be used to create any suitable embodiment of the system. In some embodiments, steps of the method 600 may be performed in a different order than that shown in the flowchart.

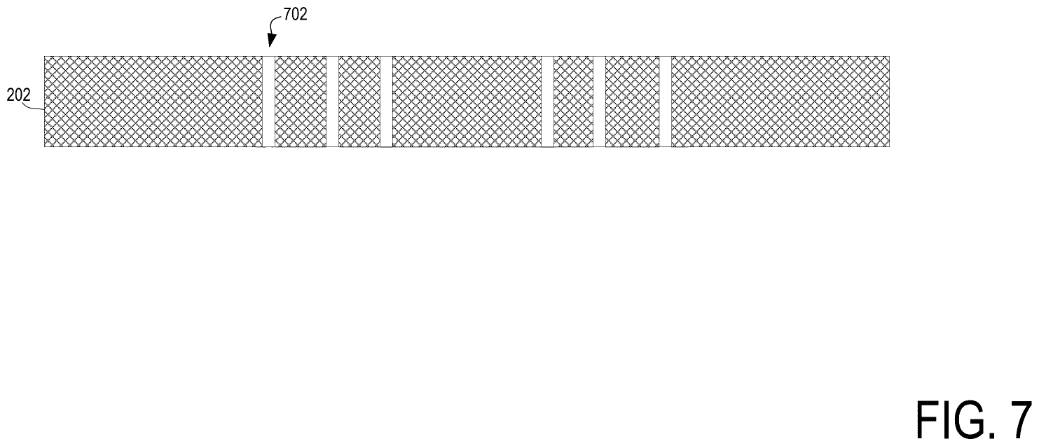

The method 600 begins in block 602, in which a substrate core 202 is prepared, such as by dicing, polishing, etc. In block 604, holes 702 or cavities are formed in the substrate core, as shown in FIG. 7. In an illustrative embodiment, laser-induced deep etching (LIDE) is used to form the holes 702. In other embodiments, other techniques may be used, such as laser drilling, mechanical drilling, etching, etc. In some embodiments, a liner may be positioned in the hole 702 such that the liner is positioned around an outside perimeter of the cavities.

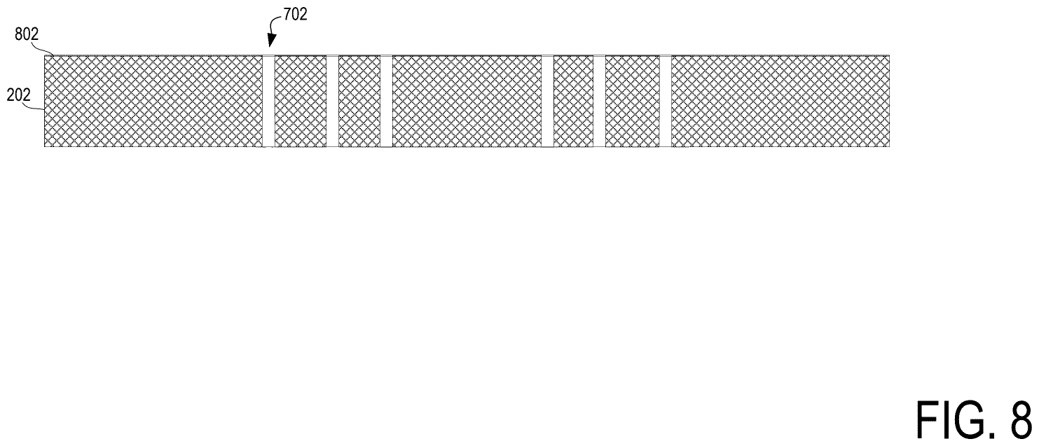

In block 606, a seed layer 802, such as a copper seed layer, may be formed on the top surface of the core 202, as shown in FIG. 8. In an illustrative embodiment, the copper seed layer 802 is formed using electroless plating. In other embodiments, the copper seed layer 802 may be formed in a different manner, such as laminating on a sheet of copper. The seed layer 802 may have any suitable thickness, such as 0.1-5 micrometers.

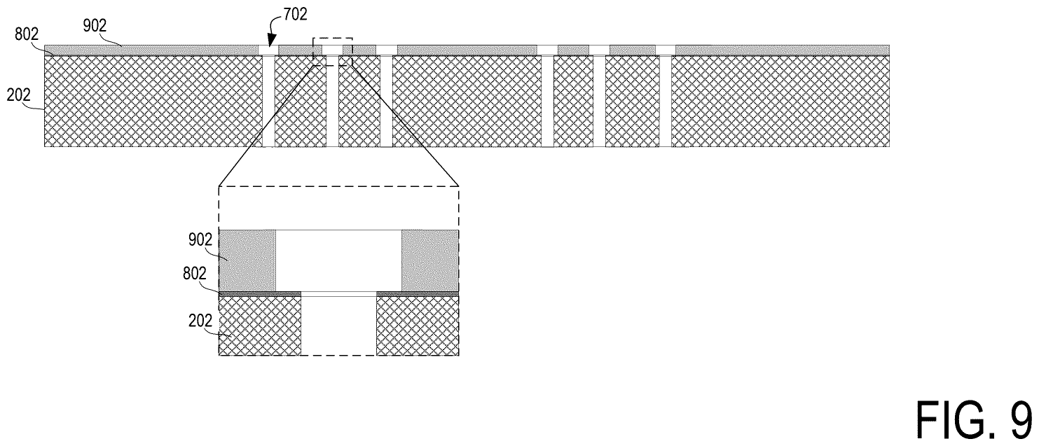

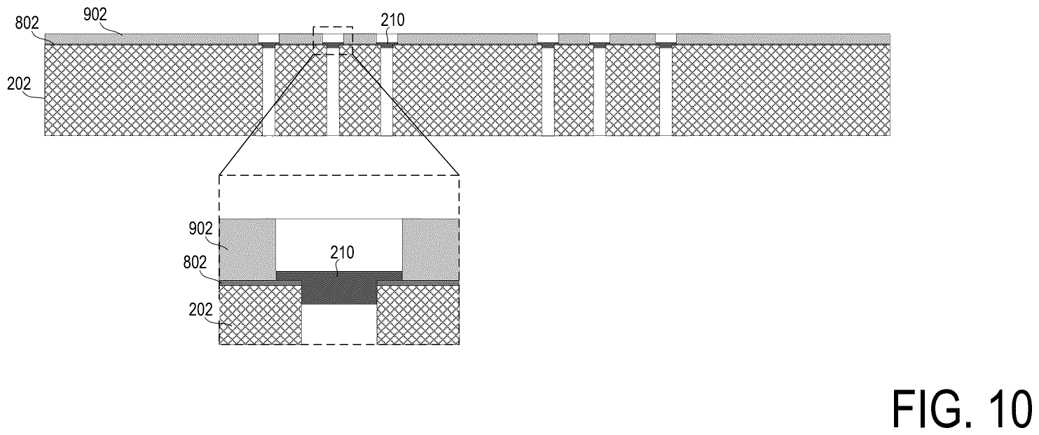

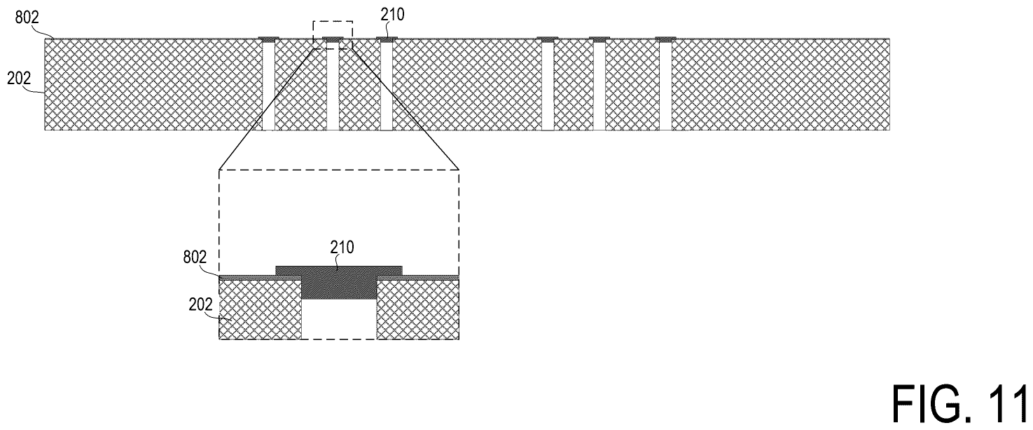

In block 608, photoresist 902 is patterned on the copper seed layer 802, defining the position of the via caps 210, as shown in FIG. 9. In block 610, additional material is electroplated onto the seed layer 802, forming a via cap 210, as shown in FIG. 10. In block 612, the photoresist 902 is removed, as shown in FIG. 11. In block 614, the substrate core 202 is flipped over.

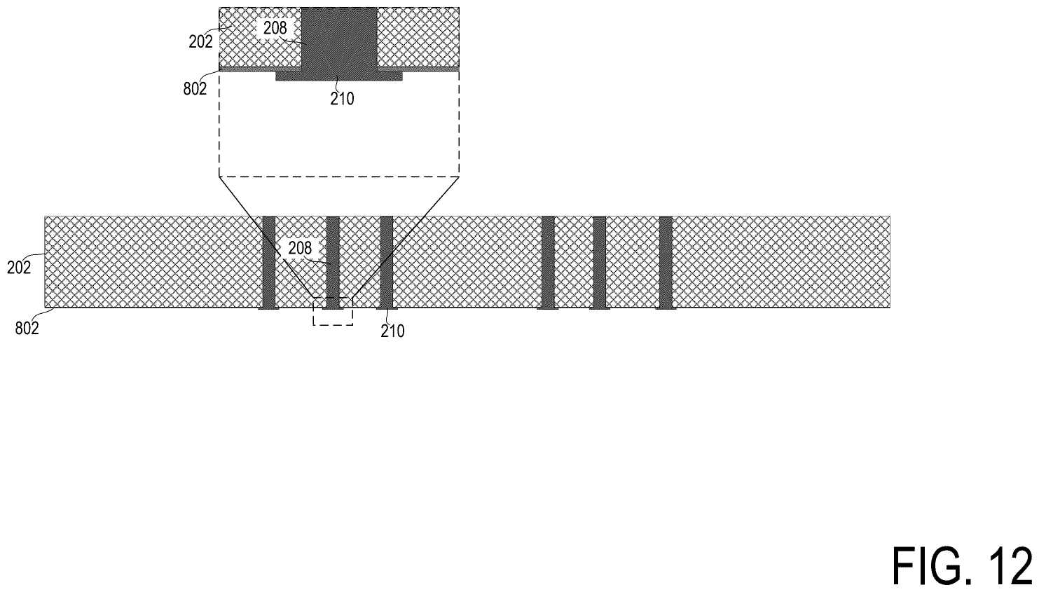

In block 616, the through-glass vias 208 are formed using bottom-up plating, as shown in FIG. 12. It should be appreciated that, in the illustrative embodiment, the electroplating technique used to form the vias 208 only deposits additional material (e.g., copper) onto existing layers of that material. As such, the vias 208 grow from the via caps 210 through the holes defined in the substrate core 202, but the vias 208 are not anchored to the substrate core 202.

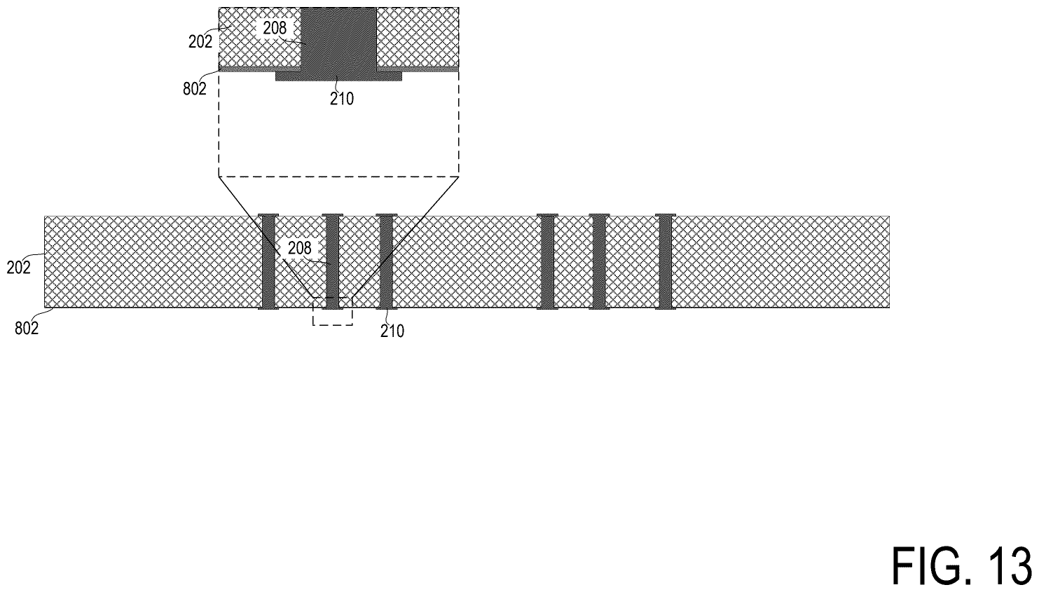

In block 618, in some embodiments, a via cap 210 is formed on top of the via 208, as shown in FIG. 13. In other embodiments, a via cap 210 is not formed on top of the via 208.

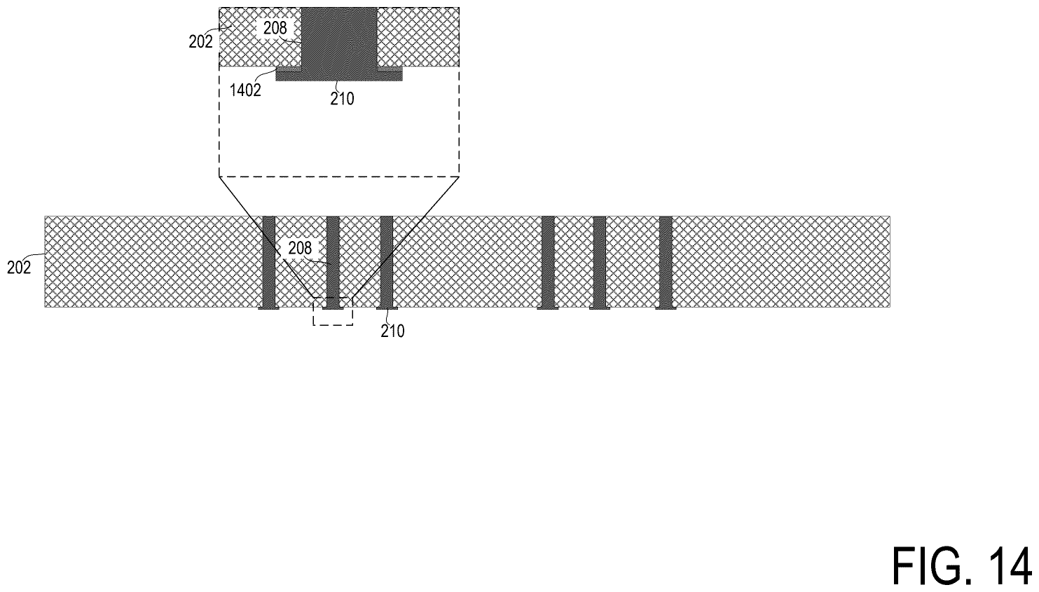

In block 620, the seed layer 802 is removed, as shown in FIG. 14. It should be appreciated that, in the illustrative embodiment, a fragment of the seed layer 1402 remains under the via cap 210. As that fragment of the seed layer 1402 is anchored to the surface of the substrate core 202, the via cap 210 and the via 208 is anchored to the surface of the substrate core 202. It should be appreciated that, in a microscopic view such as using a TEM or SEM, there may be an observable interface between the seed layer 1402 and the via cap 210. For example, the grain structure may be different in the seed layer 1402 than in the via cap 210.

After the via 208 is formed and the seed layer 802 is removed, additional processing may proceed. For example, the build-up layers 204, 206 may be built up on the substrate core 202, one or more dies 104, 106 are mounted on the substrate, etc., completing the integrated circuit component 100, as shown in FIG. 2.

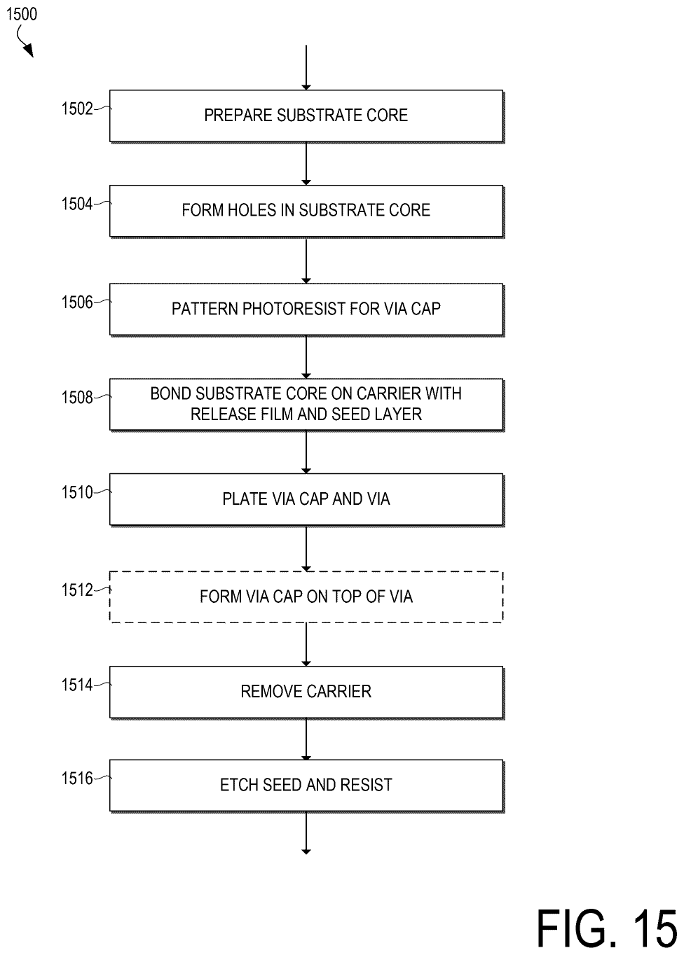

Referring now to FIG. 15, in one embodiment, a flowchart for a method 1500 for creating the integrated circuit component 100 is shown. The method 1500 may be executed by a technician and/or by one or more automated machines. In some embodiments, one or more machines may be programmed to do some or all of the steps of the method 1500. Such a machine may include, e.g., a memory, a processor, data storage, etc. The memory and/or data storage may store instructions that, when executed by the machine, cause the machine to perform some or all of the steps of the method 1500. The method 1500 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 1500 is merely one embodiment of a method to create one embodiment of a system and other methods may be used to create any suitable embodiment of the system. In some embodiments, steps of the method 1500 may be performed in a different order than that shown in the flowchart.

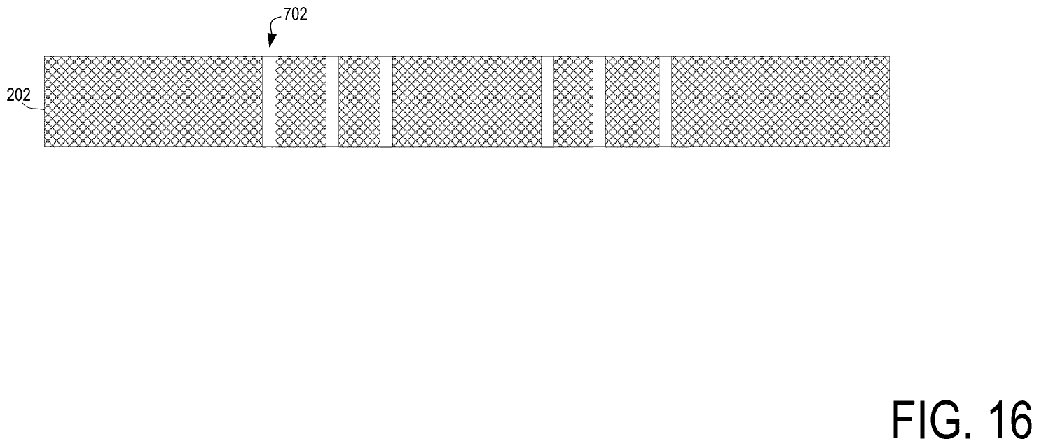

The method 1500 begins in block 1502, in which a substrate core 202 is prepared, such as by dicing, polishing, etc. In block 1504, holes 702 are formed in the substrate core, as shown in FIG. 16. In an illustrative embodiment, laser-induced deep etching (LIDE) is used to form the holes 702. In other embodiments, other techniques may be used, such as laser drilling, mechanical drilling, etching, etc.

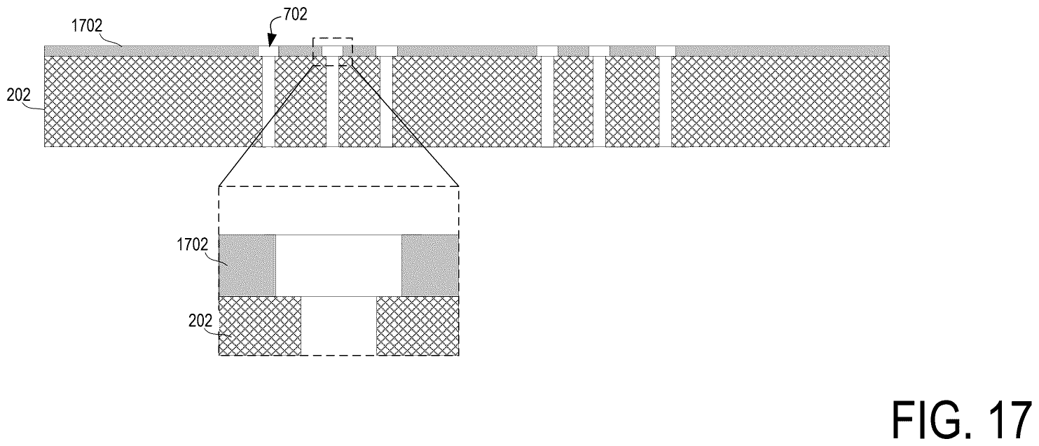

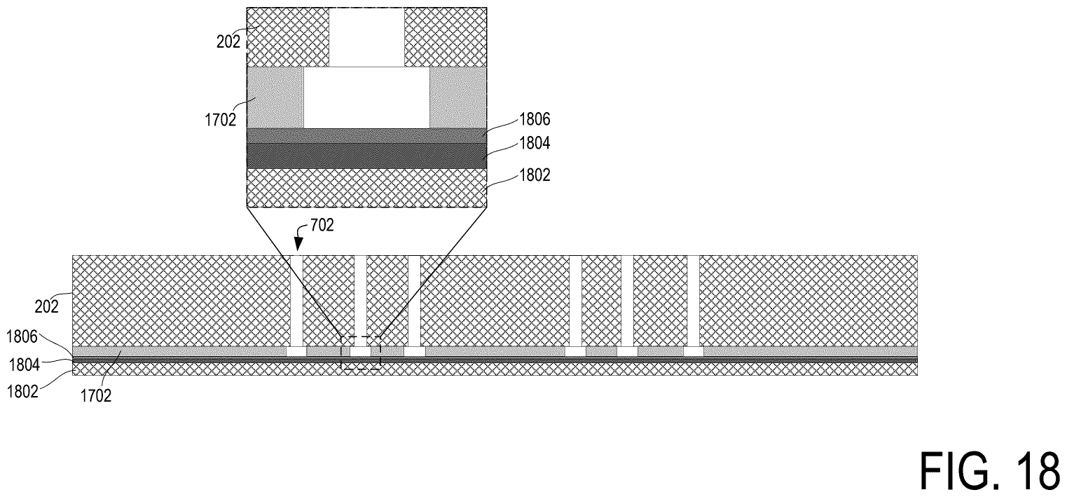

In block 1506, photoresist 1702 is patterned on the substrate core 202, defining the position of the via caps 210, as shown in FIG. 17. In block 1508, the substrate core 202 is mounted on a carrier 1802 and flipped over, as shown in FIG. 18. The carrier 1802 may be, e.g., a silicon or other substrate, a glass substrate, a tape material, and/or the like. In an illustrative embodiment, the carrier 1802 has a release film 1804 on a surface of the carrier 1802 and a seed layer formed on the release film 1804.

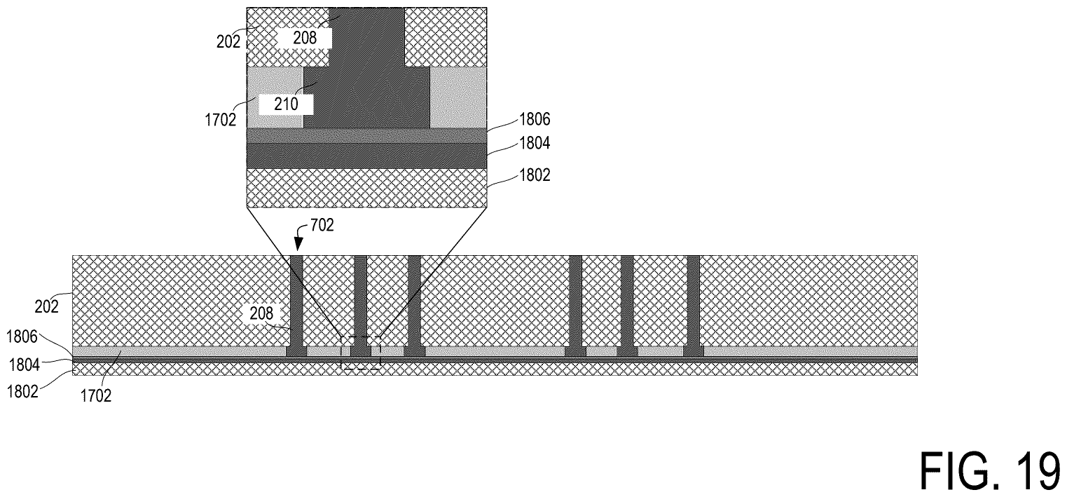

In block 1510, additional material is electroplated onto the seed layer 802, forming a via cap 210 and via 208, as shown in FIG. 19. Similar to the method 600, in the illustrative embodiment, the electroplating technique used to form the vias 208 and via caps 210 only deposits additional material (e.g., copper) onto existing layers of that material. As such, the vias 208 and via caps 210 grow from the seed layer 1806 through the holes defined in the substrate core 202, but the vias 208 and via caps 210 are not anchored to the substrate core 202.

In block 1512, in some embodiments, a via cap 210 is formed on top of the via 208. In other embodiments, a via cap 210 is not formed on top of the via 208.

In block 1514, the carrier 1802 is removed. To do so, in the illustrative embodiment, the release film 1804 is removed, such as by shining a laser through the carrier 1802 to ablate or otherwise remove the release film 1804. In block 1516, the seed layer 1806 and photoresist 1702 are etched away. Additional processing may then be used to form the build-up layers 204, 206, mount dies 104, 106 on the circuit board 102, etc.

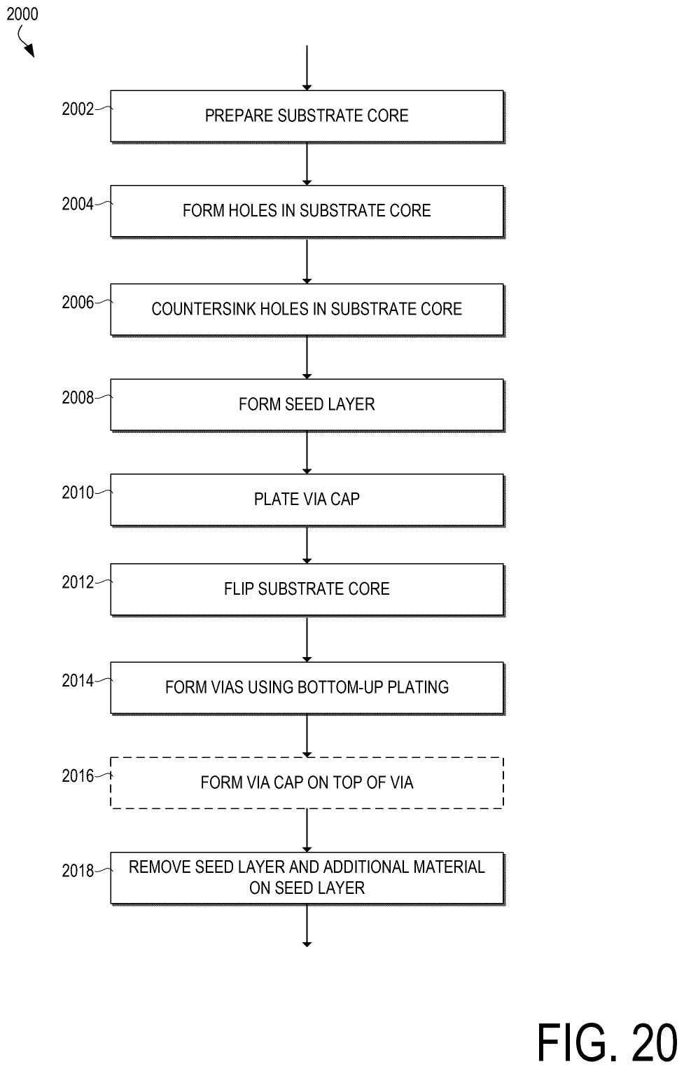

Referring now to FIG. 20, in one embodiment, a flowchart for a method 2000 for creating the integrated circuit component 100 is shown. The method 2000 may be executed by a technician and/or by one or more automated machines. In some embodiments, one or more machines may be programmed to do some or all of the steps of the method 2000. Such a machine may include, e.g., a memory, a processor, data storage, etc. The memory and/or data storage may store instructions that, when executed by the machine, cause the machine to perform some or all of the steps of the method 2000. The method 2000 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 2000 is merely one embodiment of a method to create one embodiment of a system and other methods may be used to create any suitable embodiment of the system. In some embodiments, steps of the method 2000 may be performed in a different order than that shown in the flowchart.

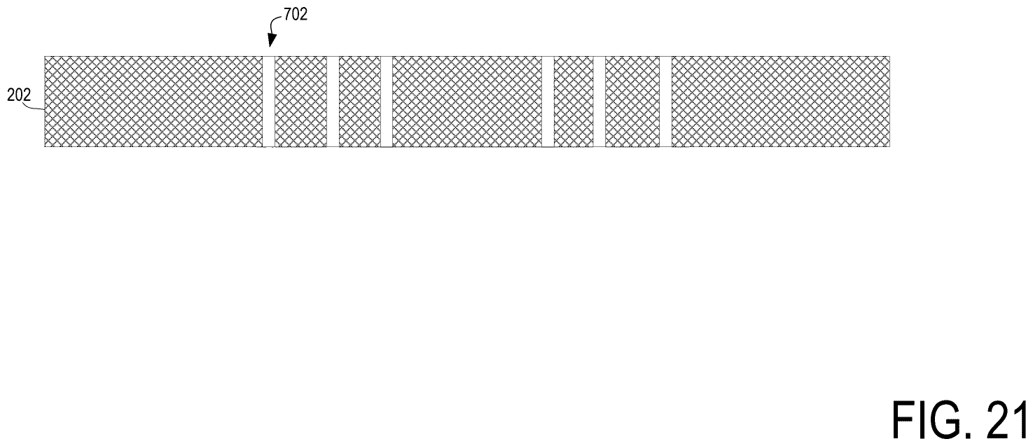

The method 2000 begins in block 2002, in which a substrate core 202 is prepared, such as by dicing, polishing, etc. In block 2004, holes 702 are formed in the substrate core, as shown in FIG. 21. In an illustrative embodiment, laser-induced deep etching (LIDE) is used to form the holes 702. In other embodiments, other techniques may be used, such as laser drilling, mechanical drilling, etching, etc.

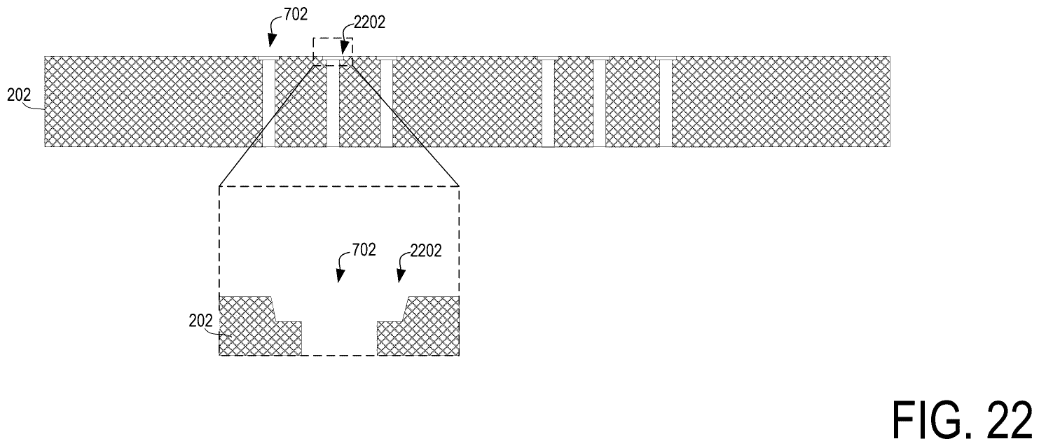

In block 2006, holes 2202 are countersunk in the substrate core 202 around the holes 702, as shown in FIG. 22. In an illustrative embodiment, laser-induced deep etching (LIDE) is used to form the holes 2202. In other embodiments, other techniques may be used, such as laser drilling, mechanical drilling, etching, etc.

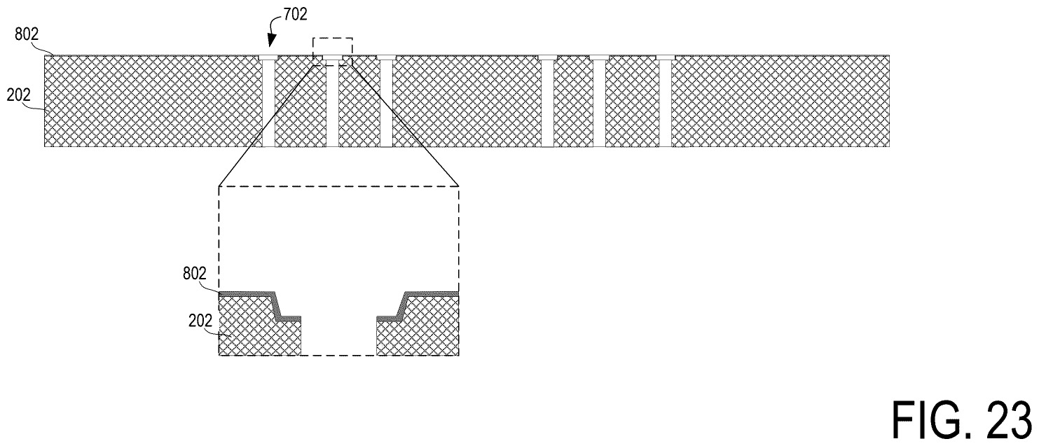

In block 2008, a seed layer 802, such as a copper seed layer, may be formed on the top surface of the core 202, as shown in FIG. 23. In an illustrative embodiment, the copper seed layer 802 is formed using electroless plating. In other embodiments, the copper seed layer 802 may be formed in a different manner, such as laminating on a sheet of copper.

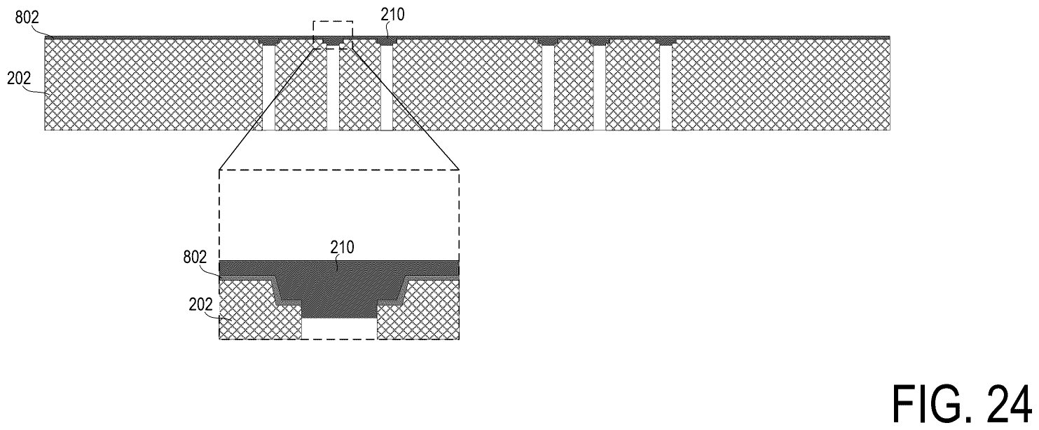

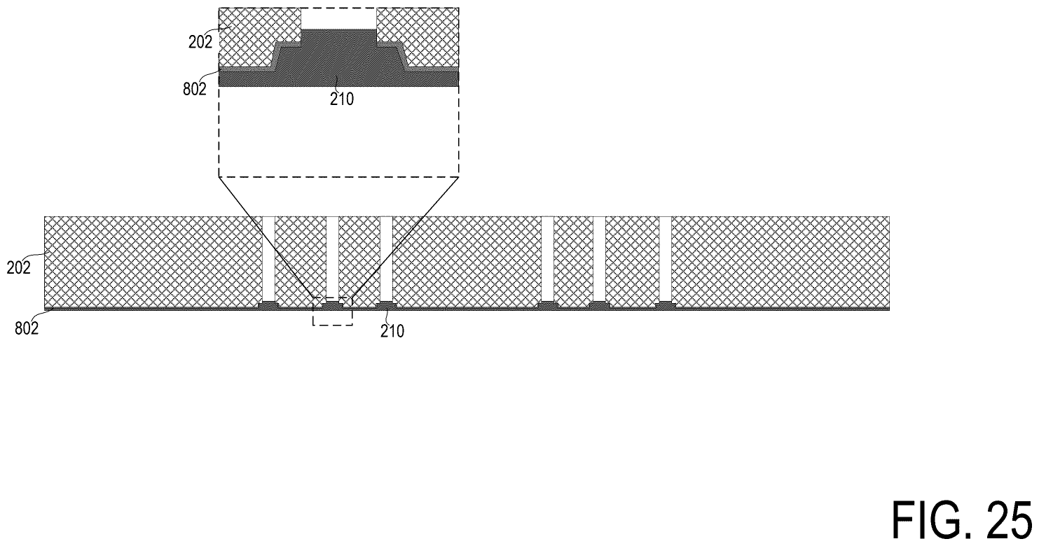

In block 2010, additional material is electroplated onto the seed layer 802, forming a via cap 210, as shown in FIG. 24. In block 2012, the substrate core 202 is flipped over, as shown in FIG. 25.

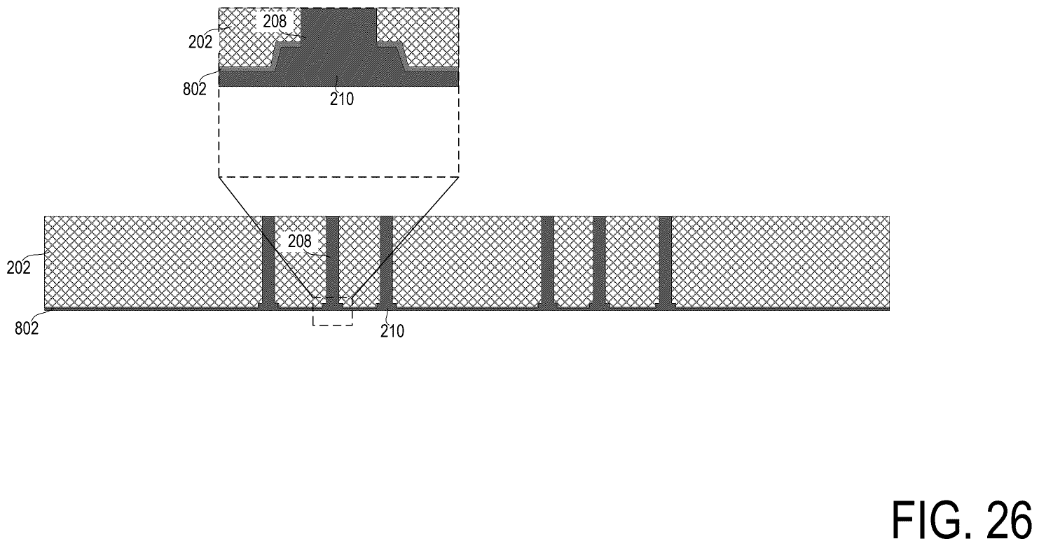

In block 2014, the vias 208 are formed using bottom-up plating, as shown in FIG. 26. As discussed before, in the illustrative embodiment, the electroplating technique used to form the vias 208 only deposits additional material (e.g., copper) onto existing layers of that material. As such, the vias 208 grow from the via caps 210 through the holes defined in the substrate core 202, but the vias 208 are not anchored to the substrate core 202. However, in the illustrative embodiment, the via caps 210 are anchored to the seed layer 802, including in the countersunk hole.

In block 2016, in some embodiments, a via cap 210 is formed on top of the via 208. In other embodiments, a via cap 210 is not formed on top of the via 208.

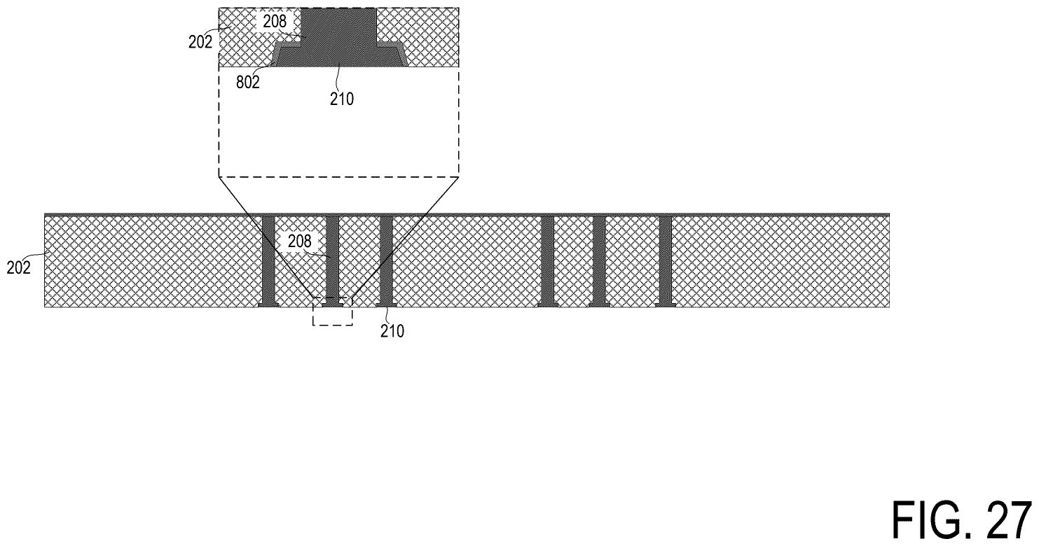

In block 2018, the seed layer 802 is removed, as shown in FIG. 27. In an illustrative embodiment, part of the via cap 210 may be removed until the via cap 210 is flush with the substrate core 202, as shown in FIG. 27. In other embodiments, the via cap 210 may extend past a plane defined by the surface of the substrate core, even when the via cap 210 is countersunk.

After the via 208 is formed and the seed layer 802 is removed, additional processing may proceed. For example, the build-up layers 204, 206 may be built up on the substrate core 202, one or more dies 104, 106 are mounted on the substrate, etc., completing the integrated circuit component 100, as shown in FIG. 2.

It should be appreciated that the integrated circuit component 100 and other integrated circuit components described herein may have additional components not shown, such as additional semiconductor dies, active component, passive components, heat management components such as integrated heat spreaders and heat sinks, etc. In some embodiments, vias 208 may be embedded in a circuit board 102 below a die 104 in an integrated circuit component 100, as shown in several figures above. In other embodiments, the vias 208 may be embedded in any suitable circuit board 102, such as a motherboard, daughterboard, riser board, power distribution board, mezzanine board, auxiliary board, and/or the like.

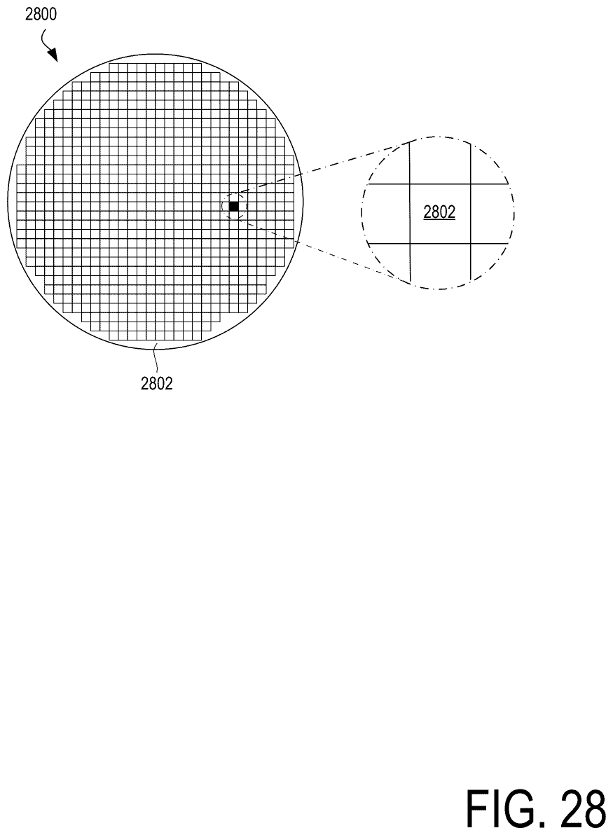

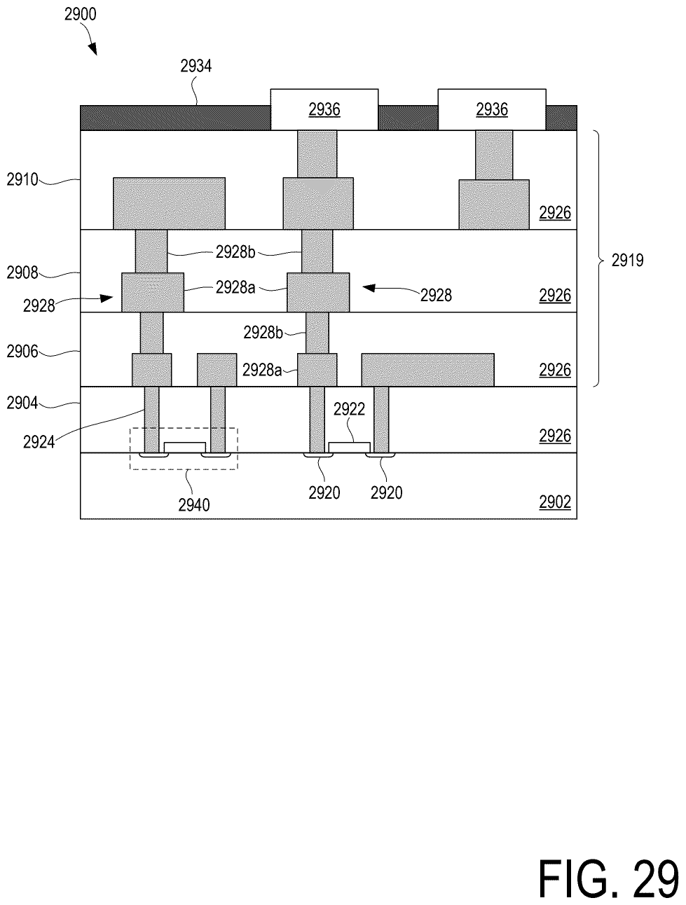

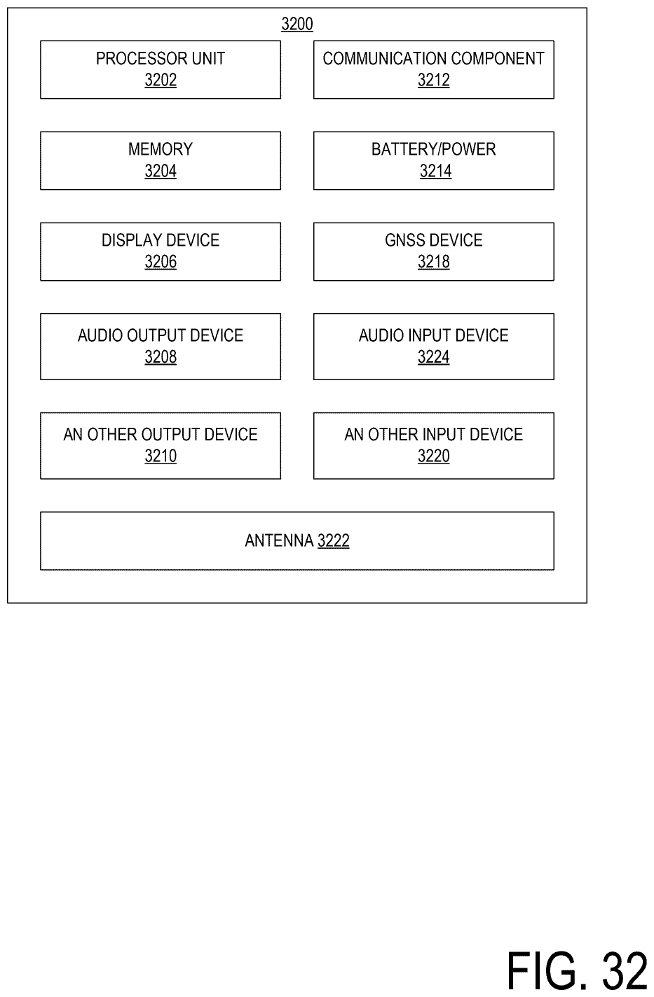

FIG. 28 is a top view of a wafer 2800 and dies 2802 that may be included in any of the integrated circuit components 100 disclosed herein (e.g., as any suitable ones of the dies 104, 106). The wafer 2800 may be composed of semiconductor material and may include one or more dies 2802 having integrated circuit structures formed on a surface of the wafer 2800. The individual dies 2802 may be a repeating unit of an integrated circuit product that includes any suitable integrated circuit. After the fabrication of the semiconductor product is complete, the wafer 2800 may undergo a singulation process in which the dies 2802 are separated from one another to provide discrete “chips” of the integrated circuit product. The die 2802 may be any of the dies 104, 106 disclosed herein. The die 2802 may include one or more transistors (e.g., some of the transistors 2940 of FIG. 29, discussed below), supporting circuitry to route electrical signals to the transistors, passive components (e.g., signal traces, resistors, capacitors, or inductors), and/or any other integrated circuit components. In some embodiments, the wafer 2800 or the die 2802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2802. For example, a memory array formed by multiple memory devices may be formed on a same die 2802 as a processor unit (e.g., the processor unit 3202 of FIG. 32) or other logic that is configured to store information in the memory devices or execute instructions stored in the memory array. Various ones of the integrated circuit components 100 disclosed herein may be manufactured using a die-to-wafer assembly technique in which some dies 104, 106 are attached to a wafer 2800 that include others of the dies 104, 106, and the wafer 2800 is subsequently singulated.

FIG. 29 is a cross-sectional side view of an integrated circuit device 2900 that may be included in any of the integrated circuit components 100 disclosed herein (e.g., in any of the dies 104, 106). One or more of the integrated circuit devices 2900 may be included in one or more dies 2802 (FIG. 28). The integrated circuit device 2900 may be formed on a die substrate 2902 (e.g., the wafer 2800 of FIG. 28) and may be included in a die (e.g., the die 2802 of FIG. 28). The die substrate 2902 may be a semiconductor substrate composed of semiconductor material systems including, for example, n-type or p-type materials systems (or a combination of both). The die substrate 2902 may include, for example, a crystalline substrate formed using a bulk silicon or a silicon-on-insulator (SOI) substructure. In some embodiments, the die substrate 2902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2902. Although a few examples of materials from which the die substrate 2902 may be formed are described here, any material that may serve as a foundation for an integrated circuit device 2900 may be used. The die substrate 2902 may be part of a singulated die (e.g., the dies 2802 of FIG. 28) or a wafer (e.g., the wafer 2800 of FIG. 28).

The integrated circuit device 2900 may include one or more device layers 2904 disposed on the die substrate 2902. The device layer 2904 may include features of one or more transistors 2940 (e.g., metal oxide semiconductor field-effect transistors (MOSFETs)) formed on the die substrate 2902. The transistors 2940 may include, for example, one or more source and/or drain (S/D) regions 2920, a gate 2922 to control current flow between the S/D regions 2920, and one or more S/D contacts 2924 to route electrical signals to/from the S/D regions 2920. The transistors 2940 may include additional features not depicted for the sake of clarity, such as device isolation regions, gate contacts, and the like. The transistors 2940 are not limited to the type and configuration depicted in FIG. 29 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

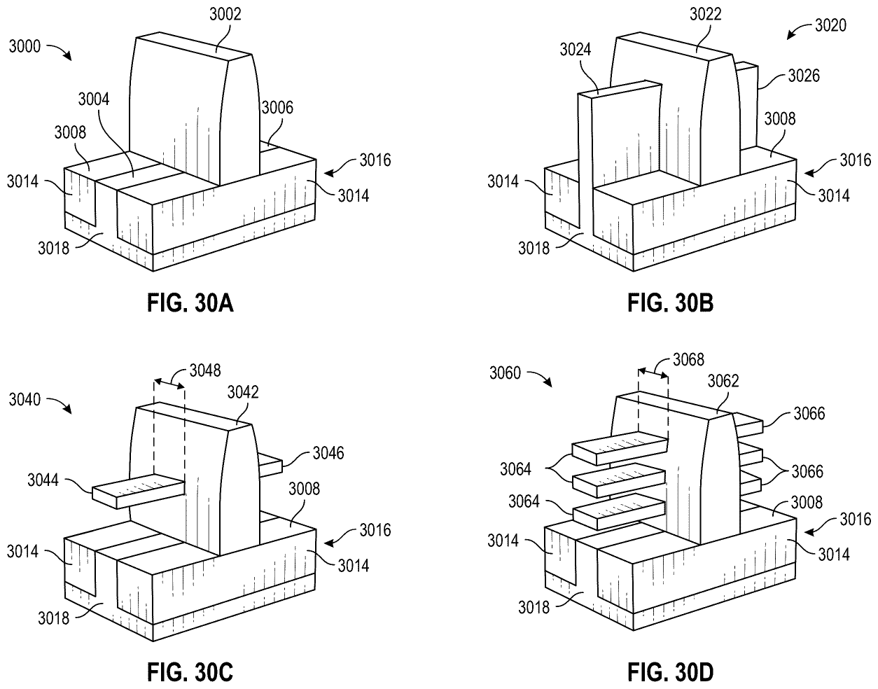

FIGS. 30A-30D are simplified perspective views of example planar, FinFET, gate-all-around, and stacked gate-all-around transistors. The transistors illustrated in FIGS. 30A-30D are formed on a substrate 3016 having a surface 3008. Isolation regions 3014 separate the source and drain regions of the transistors from other transistors and from a bulk region 3018 of the substrate 3016.

FIG. 30A is a perspective view of an example planar transistor 3000 comprising a gate 3002 that controls current flow between a source region 3004 and a drain region 3006. The transistor 3000 is planar in that the source region 3004 and the drain region 3006 are planar with respect to the substrate surface 3008.

FIG. 30B is a perspective view of an example FinFET transistor 3020 comprising a gate 3022 that controls current flow between a source region 3024 and a drain region 3026. The transistor 3020 is non-planar in that the source region 3024 and the drain region 3026 comprise “fins” that extend upwards from the substrate surface 3008. As the gate 3022 encompasses three sides of the semiconductor fin that extends from the source region 3024 to the drain region 3026, the transistor 3020 can be considered a tri-gate transistor. FIG. 30B illustrates one S/D fin extending through the gate 3022, but multiple S/D fins can extend through the gate of a FinFET transistor.

FIG. 30C is a perspective view of a gate-all-around (GAA) transistor 3040 comprising a gate 3042 that controls current flow between a source region 3044 and a drain region 3046. The transistor 3040 is non-planar in that the source region 3044 and the drain region 3046 are elevated from the substrate surface 3008.

FIG. 30D is a perspective view of a GAA transistor 3060 comprising a gate 3062 that controls current flow between multiple elevated source regions 3064 and multiple elevated drain regions 3066. The transistor 3060 is a stacked GAA transistor as the gate controls the flow of current between multiple elevated S/D regions stacked on top of each other. The transistors 3040 and 3060 are considered gate-all-around transistors as the gates encompass all sides of the semiconductor portions that extends from the source regions to the drain regions. The transistors 3040 and 3060 can alternatively be referred to as nanowire, nanosheet, or nanoribbon transistors depending on the width (e.g., widths 3048 and 3068 of transistors 3040 and 3060, respectively) of the semiconductor portions extending through the gate.

Returning to FIG. 29, a transistor 2940 may include a gate 2922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 2940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2940 along the source-channel-drain direction, the gate electrode may consist of a U-shaped structure that includes a bottom portion substantially parallel to the surface of the die substrate 2902 and two sidewall portions that are substantially perpendicular to the top surface of the die substrate 2902. In other embodiments, at least one of the metal layers that form the gate electrode may simply be a planar layer that is substantially parallel to the top surface of the die substrate 2902 and does not include sidewall portions substantially perpendicular to the top surface of the die substrate 2902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2920 may be formed within the die substrate 2902 adjacent to the gate 2922 of individual transistors 2940. The S/D regions 2920 may be formed using an implantation/diffusion process or an etching/deposition process, for example. In the former process, dopants such as boron, aluminum, antimony, phosphorous, or arsenic may be ion-implanted into the die substrate 2902 to form the S/D regions 2920. An annealing process that activates the dopants and causes them to diffuse farther into the die substrate 2902 may follow the ion-implantation process. In the latter process, the die substrate 2902 may first be etched to form recesses at the locations of the S/D regions 2920. An epitaxial deposition process may then be carried out to fill the recesses with material that is used to fabricate the S/D regions 2920. In some implementations, the S/D regions 2920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2920 may be formed using one or more alternate semiconductor materials such as germanium or a group III-V material or alloy. In further embodiments, one or more layers of metal and/or metal alloys may be used to form the S/D regions 2920.

Electrical signals, such as power and/or input/output (I/O) signals, may be routed to and/or from the devices (e.g., transistors 2940) of the device layer 2904 through one or more interconnect layers disposed on the device layer 2904 (illustrated in FIG. 29 as interconnect layers 2906-2910). For example, electrically conductive features of the device layer 2904 (e.g., the gate 2922 and the S/D contacts 2924) may be electrically coupled with the interconnect structures 2928 of the interconnect layers 2906-2910. The one or more interconnect layers 2906-2910 may form a metallization stack (also referred to as an “ILD stack”) 2919 of the integrated circuit device 2900.

The interconnect structures 2928 may be arranged within the interconnect layers 2906-2910 to route electrical signals according to a wide variety of designs; in particular, the arrangement is not limited to the particular configuration of interconnect structures 2928 depicted in FIG. 29. Although a particular number of interconnect layers 2906-2910 is depicted in FIG. 29, embodiments of the present disclosure include integrated circuit devices having more or fewer interconnect layers than depicted.

In some embodiments, the interconnect structures 2928 may include lines 2928a and/or vias 2928b filled with an electrically conductive material such as a metal. The lines 2928a may be arranged to route electrical signals in a direction of a plane that is substantially parallel with a surface of the die substrate 2902 upon which the device layer 2904 is formed. For example, the lines 2928a may route electrical signals in a direction in and out of the page and/or in a direction across the page. The vias 2928b may be arranged to route electrical signals in a direction of a plane that is substantially perpendicular to the surface of the die substrate 2902 upon which the device layer 2904 is formed. In some embodiments, the vias 2928b may electrically couple lines 2928a of different interconnect layers 2906-2910 together.

The interconnect layers 2906-2910 may include a dielectric material 2926 disposed between the interconnect structures 2928, as shown in FIG. 29. In some embodiments, dielectric material 2926 disposed between the interconnect structures 2928 in different ones of the interconnect layers 2906-2910 may have different compositions; in other embodiments, the composition of the dielectric material 2926 between different interconnect layers 2906-2910 may be the same. The device layer 2904 may include a dielectric material 2926 disposed between the transistors 2940 and a bottom layer of the metallization stack as well. The dielectric material 2926 included in the device layer 2904 may have a different composition than the dielectric material 2926 included in the interconnect layers 2906-2910; in other embodiments, the composition of the dielectric material 2926 in the device layer 2904 may be the same as a dielectric material 2926 included in any one of the interconnect layers 2906-2910.

A first interconnect layer 2906 (referred to as Metal 1 or “M1”) may be formed directly on the device layer 2904. In some embodiments, the first interconnect layer 2906 may include lines 2928a and/or vias 2928b, as shown. The lines 2928a of the first interconnect layer 2906 may be coupled with contacts (e.g., the S/D contacts 2924) of the device layer 2904. The vias 2928b of the first interconnect layer 2906 may be coupled with the lines 2928a of a second interconnect layer 2908.

The second interconnect layer 2908 (referred to as Metal 2 or “M2”) may be formed directly on the first interconnect layer 2906. In some embodiments, the second interconnect layer 2908 may include via 2928b to couple the lines 2928a-2928b of the second interconnect layer 2908 with the lines 2928a of a third interconnect layer 2910. Although the lines 2928a and the vias 2928b are structurally delineated with a line within individual interconnect layers for the sake of clarity, the lines 2928a and the vias 2928b may be structurally and/or materially contiguous (e.g., simultaneously filled during a dual-damascene process) in some embodiments.

The third interconnect layer 2910 (referred to as Metal 3 or “M3”) (and additional interconnect layers, as desired) may be formed in succession on the second interconnect layer 2908 according to similar techniques and configurations described in connection with the second interconnect layer 2908 or the first interconnect layer 2906. In some embodiments, the interconnect layers that are “higher up” in the metallization stack 2919 in the integrated circuit device 2900 (i.e., farther away from the device layer 2904) may be thicker that the interconnect layers that are lower in the metallization stack 2919, with lines 2928a and vias 2928b in the higher interconnect layers being thicker than those in the lower interconnect layers.

The integrated circuit device 2900 may include a solder resist material 2934 (e.g., polyimide or similar material) and one or more conductive contacts 2936 formed on the interconnect layers 2906-2910. In FIG. 29, the conductive contacts 2936 are illustrated as taking the form of bond pads. The conductive contacts 2936 may be electrically coupled with the interconnect structures 2928 and configured to route the electrical signals of the transistor(s) 2940 to external devices. For example, solder bonds may be formed on the one or more conductive contacts 2936 to mechanically and/or electrically couple an integrated circuit die including the integrated circuit device 2900 with another component (e.g., a printed circuit board). The integrated circuit device 2900 may include additional or alternate structures to route the electrical signals from the interconnect layers 2906-2910; for example, the conductive contacts 2936 may include other analogous features (e.g., posts) that route the electrical signals to external components. The conductive contacts 2936 may serve as the conductive contacts 222, as appropriate.

In some embodiments in which the integrated circuit device 2900 is a double-sided die, the integrated circuit device 2900 may include another metallization stack (not shown) on the opposite side of the device layer(s) 2904. This metallization stack may include multiple interconnect layers as discussed above with reference to the interconnect layers 2906-2910, to provide conductive pathways (e.g., including conductive lines and vias) between the device layer(s) 2904 and additional conductive contacts (not shown) on the opposite side of the integrated circuit device 2900 from the conductive contacts 2936. These additional conductive contacts may serve as the conductive contacts 222, as appropriate.

In other embodiments in which the integrated circuit device 2900 is a double-sided die, the integrated circuit device 2900 may include one or more through silicon vias (TSVs) through the die substrate 2902; these TSVs may make contact with the device layer(s) 2904, and may provide conductive pathways between the device layer(s) 2904 and additional conductive contacts (not shown) on the opposite side of the integrated circuit device 2900 from the conductive contacts 2936. These additional conductive contacts may serve as the conductive contacts 222, as appropriate. In some embodiments, TSVs extending through the substrate can be used for routing power and ground signals from conductive contacts on the opposite side of the integrated circuit device 2900 from the conductive contacts 2936 to the transistors 2940 and any other components integrated into the die, and the metallization stack 2919 can be used to route I/O signals from the conductive contacts 2936 to transistors 2940 and any other components integrated into the die.

Multiple integrated circuit devices 2900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

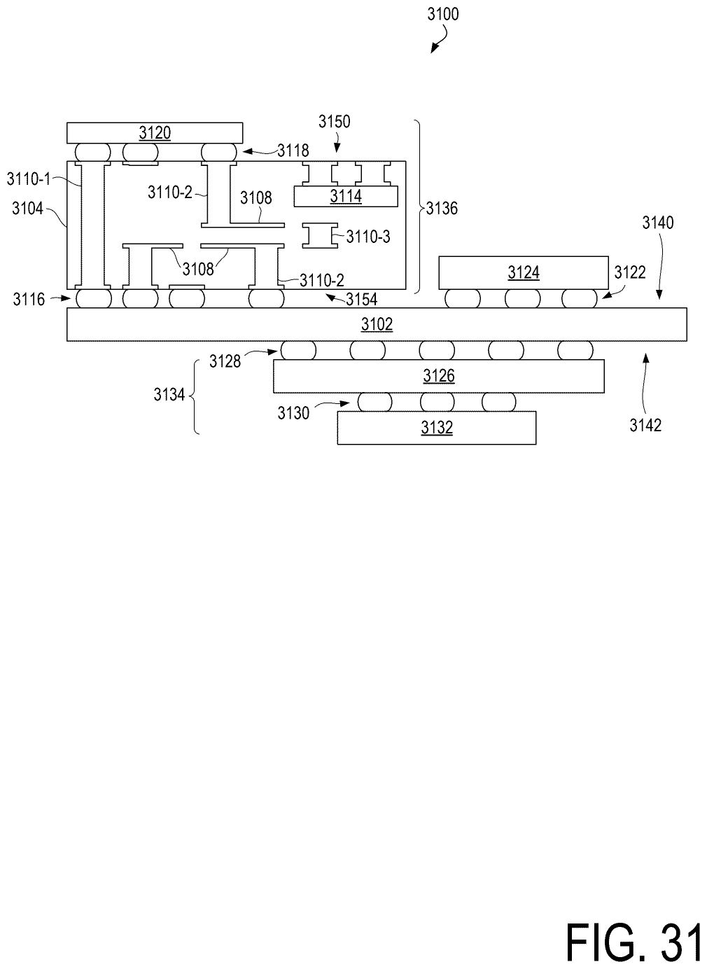

FIG. 31 is a cross-sectional side view of an integrated circuit device assembly 3100 that may include any of the integrated circuit components 100 disclosed herein. In some embodiments, the integrated circuit device assembly 3100 may be an integrated circuit component 100. The integrated circuit device assembly 3100 includes a number of components disposed on a circuit board 3102 (which may be a motherboard, system board, mainboard, etc.). The integrated circuit device assembly 3100 includes components disposed on a first face 3140 of the circuit board 3102 and an opposing second face 3142 of the circuit board 3102; generally, components may be disposed on one or both faces 3140 and 3142. Any of the integrated circuit components discussed below with reference to the integrated circuit device assembly 3100 may take the form of any suitable ones of the embodiments of the integrated circuit components 100 disclosed herein.

In some embodiments, the circuit board 3102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 3102. In other embodiments, the circuit board 3102 may be a non-PCB substrate. In some embodiments the circuit board 3102 may be, for example, the circuit board 102. The integrated circuit device assembly 3100 illustrated in FIG. 31 includes a package-on-interposer structure 3136 coupled to the first face 3140 of the circuit board 3102 by coupling components 3116. The coupling components 3116 may electrically and mechanically couple the package-on-interposer structure 3136 to the circuit board 3102, and may include solder balls (as shown in FIG. 31), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 3116 may serve as the coupling components illustrated or described for any of the substrate assembly or substrate assembly components described herein, as appropriate.

The package-on-interposer structure 3136 may include an integrated circuit component 3120 coupled to an interposer 3104 by coupling components 3118. The coupling components 3118 may take any suitable form for the application, such as the forms discussed above with reference to the coupling components 3116. Although a single integrated circuit component 3120 is shown in FIG. 31, multiple integrated circuit components may be coupled to the interposer 3104; indeed, additional interposers may be coupled to the interposer 3104. The interposer 3104 may provide an intervening substrate used to bridge the circuit board 3102 and the integrated circuit component 3120.

The integrated circuit component 3120 may be a packaged or unpacked integrated circuit product that includes one or more integrated circuit dies (e.g., the die 2802 of FIG. 28, the integrated circuit device 2900 of FIG. 29) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 3120, a single monolithic integrated circuit die comprises solder bumps attached to contacts on the die. The solder bumps allow the die to be directly attached to the interposer 3104. The integrated circuit component 3120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 3120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 3120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 3120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 3104 may spread connections to a wider pitch or reroute a connection to a different connection. For example, the interposer 3104 may couple the integrated circuit component 3120 to a set of ball grid array (BGA) conductive contacts of the coupling components 3116 for coupling to the circuit board 3102. In the embodiment illustrated in FIG. 31, the integrated circuit component 3120 and the circuit board 3102 are attached to opposing sides of the interposer 3104; in other embodiments, the integrated circuit component 3120 and the circuit board 3102 may be attached to a same side of the interposer 3104. In some embodiments, three or more components may be interconnected by way of the interposer 3104.

In some embodiments, the interposer 3104 may be formed as a PCB, including multiple metal layers separated from one another by layers of dielectric material and interconnected by electrically conductive vias. In some embodiments, the interposer 3104 may be formed of an epoxy resin, a fiberglass-reinforced epoxy resin, an epoxy resin with inorganic fillers, a ceramic material, or a polymer material such as polyimide. In some embodiments, the interposer 3104 may be formed of alternate rigid or flexible materials that may include the same materials described above for use in a semiconductor substrate, such as silicon, germanium, and other group III-V and group IV materials. The interposer 3104 may include metal interconnects 3108 and vias, including but not limited to through hole vias 3110-1 (that extend from a first face 3150 of the interposer 3104 to a second face 3154 of the interposer 3104), blind vias 3110-2 (that extend from the first or second faces 3150 or 3154 of the interposer 3104 to an internal metal layer), and buried vias 3110-3 (that connect internal metal layers).

In some embodiments, the interposer 3104 can comprise a silicon interposer. Through silicon vias (TSV) extending through the silicon interposer can connect connections on a first face of a silicon interposer to an opposing second face of the silicon interposer. In some embodiments, an interposer 3104 comprising a silicon interposer can further comprise one or more routing layers to route connections on a first face of the interposer 3104 to an opposing second face of the interposer 3104.

The interposer 3104 may further include embedded devices 3114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3104. The package-on-interposer structure 3136 may take the form of any of the package-on-interposer structures known in the art.

The integrated circuit device assembly 3100 may include an integrated circuit component 3124 coupled to the first face 3140 of the circuit board 3102 by coupling components 3122. The coupling components 3122 may take the form of any of the embodiments discussed above with reference to the coupling components 3116, and the integrated circuit component 3124 may take the form of any of the embodiments discussed above with reference to the integrated circuit component 3120.

The integrated circuit device assembly 3100 illustrated in FIG. 31 includes a package-on-package structure 3134 coupled to the second face 3142 of the circuit board 3102 by coupling components 3128. The package-on-package structure 3134 may include an integrated circuit component 3126 and an integrated circuit component 3132 coupled together by coupling components 3130 such that the integrated circuit component 3126 is disposed between the circuit board 3102 and the integrated circuit component 3132. The coupling components 3128 and 3130 may take the form of any of the embodiments of the coupling components 3116 discussed above, and the integrated circuit components 3126 and 3132 may take the form of any of the embodiments of the integrated circuit component 3120 discussed above. The package-on-package structure 3134 may be configured in accordance with any of the package-on-package structures known in the art.

FIG. 32 is a block diagram of an example electrical device 3200 that may include one or more of the integrated circuit components 100 disclosed herein. For example, any suitable ones of the components of the electrical device 3200 may include one or more of the integrated circuit device assemblies 3100, integrated circuit components 3120, integrated circuit devices 2900, or integrated circuit dies 2802 disclosed herein, and may be arranged in any of the integrated circuit components 100 disclosed herein. A number of components are illustrated in FIG. 32 as included in the electrical device 3200, but any one or more of these components may be omitted or duplicated, as suitable for the application. In some embodiments, some or all of the components included in the electrical device 3200 may be attached to one or more motherboards mainboards, or system boards. In some embodiments, one or more of these components are fabricated onto a single system-on-a-chip (SoC) die.

Additionally, in various embodiments, the electrical device 3200 may not include one or more of the components illustrated in FIG. 32, but the electrical device 3200 may include interface circuitry for coupling to the one or more components. For example, the electrical device 3200 may not include a display device 3206, but may include display device interface circuitry (e.g., a connector and driver circuitry) to which a display device 3206 may be coupled. In another set of examples, the electrical device 3200 may not include an audio input device 3224 or an audio output device 3208, but may include audio input or output device interface circuitry (e.g., connectors and supporting circuitry) to which an audio input device 3224 or audio output device 3208 may be coupled.

The electrical device 3200 may include one or more processor units 3202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 3202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3200 may include a memory 3204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3204 may include memory that is located on the same integrated circuit die as the processor unit 3202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 3200 can comprise one or more processor units 3202 that are heterogeneous or asymmetric to another processor unit 3202 in the electrical device 3200. There can be a variety of differences between the processing units 3202 in a system in terms of a spectrum of metrics of merit including architectural, microarchitectural, thermal, power consumption characteristics, and the like. These differences can effectively manifest themselves as asymmetry and heterogeneity among the processor units 3202 in the electrical device 3200.

In some embodiments, the electrical device 3200 may include a communication component 3212 (e.g., one or more communication components). For example, the communication component 3212 can manage wireless communications for the transfer of data to and from the electrical device 3200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3212 may operate in accordance with other wireless protocols in other embodiments. The electrical device 3200 may include an antenna 3222 to facilitate wireless communications and/or to receive other wireless communications (such as AM or FM radio transmissions).

In some embodiments, the communication component 3212 may manage wired communications, such as electrical, optical, or any other suitable communication protocols (e.g., IEEE 802.3 Ethernet standards). As noted above, the communication component 3212 may include multiple communication components. For instance, a first communication component 3212 may be dedicated to shorter-range wireless communications such as Wi-Fi or Bluetooth, and a second communication component 3212 may be dedicated to longer-range wireless communications such as global positioning system (GPS), EDGE, GPRS, CDMA, WiMAX, LTE, EV-DO, or others. In some embodiments, a first communication component 3212 may be dedicated to wireless communications, and a second communication component 3212 may be dedicated to wired communications.

The electrical device 3200 may include battery/power circuitry 3214. The battery/power circuitry 3214 may include one or more energy storage devices (e.g., batteries or capacitors) and/or circuitry for coupling components of the electrical device 3200 to an energy source separate from the electrical device 3200 (e.g., AC line power).

The electrical device 3200 may include a display device 3206 (or corresponding interface circuitry, as discussed above). The display device 3206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3200 may include an audio output device 3208 (or corresponding interface circuitry, as discussed above). The audio output device 3208 may include any embedded or wired or wirelessly connected external device that generates an audible indicator, such as speakers, headsets, or earbuds.

The electrical device 3200 may include an audio input device 3224 (or corresponding interface circuitry, as discussed above). The audio input device 3224 may include any embedded or wired or wirelessly connected device that generates a signal representative of a sound, such as microphones, microphone arrays, or digital instruments (e.g., instruments having a musical instrument digital interface (MIDI) output). The electrical device 3200 may include a Global Navigation Satellite System (GNSS) device 3218 (or corresponding interface circuitry, as discussed above), such as a Global Positioning System (GPS) device. The GNSS device 3218 may be in communication with a satellite-based system and may determine a geolocation of the electrical device 3200 based on information received from one or more GNSS satellites, as known in the art.

The electrical device 3200 may include an other output device 3210 (or corresponding interface circuitry, as discussed above). Examples of the other output device 3210 may include an audio codec, a video codec, a printer, a wired or wireless transmitter for providing information to other devices, or an additional storage device.

The electrical device 3200 may include an other input device 3220 (or corresponding interface circuitry, as discussed above). Examples of the other input device 3220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3200 may be any other electronic device that processes data. In some embodiments, the electrical device 3200 may comprise multiple discrete physical components. Given the range of devices that the electrical device 3200 can be manifested as in various embodiments, in some embodiments, the electrical device 3200 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a substrate core, the substrate core comprising a top side and a bottom side, wherein a plurality of cavities are defined within the substrate core, wherein individual cavities of the plurality of cavities extend from the bottom side to the top side; a plurality of vias extending through the plurality of cavities defined in the substrate core, wherein individual vias of the plurality of vias are not anchored to sidewalls of a corresponding cavity of the plurality of cavities; and a plurality of via caps, wherein individual via caps of the plurality of via caps are disposed at one end of individual vias of the plurality of vias.

Example 2 includes the subject matter of Example 1, and wherein the plurality of via caps are countersunk in the substrate core such that at least part of individual via caps of the plurality of via caps extends below a plane defined by the top side of the substrate core.

Example 3 includes the subject matter of any of Examples 1 and 2, and wherein the plurality of via caps are flush with the substrate core such that no part of individual via caps of the plurality of via caps extends above the plane defined by the top side of the substrate core.

Example 4 includes the subject matter of any of Examples 1-3, and wherein individual via caps of the plurality of via caps are anchored to the top side of the substrate core.

Example 5 includes the subject matter of any of Examples 1-4, and wherein individual via caps of the plurality of via caps comprise a seed layer with a first grain structure and an electroplated layer with a second grain structure different from the first grain structure.

Example 6 includes the subject matter of any of Examples 1-5, and wherein a gap of at least 10 nanometers is present between at least part of individual vias of the plurality of vias and sidewalls of the corresponding cavity of the plurality of cavities.

Example 7 includes the subject matter of any of Examples 1-6, and wherein individual via caps of the plurality of via caps are not anchored to the substrate core.

Example 8 includes the subject matter of any of Examples 1-7, and wherein cross-sections of individual vias of the plurality of vias taken perpendicular to the individual vias do not contact the sidewalls of the corresponding cavity of the plurality of cavities.

Example 9 includes the subject matter of any of Examples 1-8, and wherein, for individual cavities of the plurality of cavities, a liner is disposed around an outside perimeter of the corresponding cavity, wherein the sidewalls of the plurality of cavities are the sidewalls of a corresponding liner.

Example 10 includes the subject matter of any of Examples 1-9, and further including a plurality of build-up layers adjacent the top side and the bottom side; and one or more semiconductor dies mounted on a build-up layer of the plurality of build-up layers.

Example 11 includes an apparatus comprising a substrate core, the substrate core comprising a top side and a bottom side, wherein a plurality of cavities are defined within the substrate core extending from the bottom side to the top side; a plurality of vias extending through the plurality of cavities defined in the substrate core, wherein a gap of at least 10 nanometers is present between at least part of individual vias of the plurality of vias and sidewalls of a corresponding cavity of the plurality of cavities; and a plurality of via caps, wherein individual via caps of the plurality of via caps are disposed at one end of individual vias of the plurality of vias.

Example 12 includes the subject matter of Example 11, and wherein individual vias of the plurality of vias are not anchored to sidewalls of the corresponding cavity of the plurality of cavities.

Example 13 includes the subject matter of any of Examples 11 and 12, and wherein the plurality of via caps are countersunk in the substrate core such that at least part of individual via caps of the plurality of via caps extends below a plane defined by the top side of the substrate core.

Example 14 includes the subject matter of any of Examples 11-13, and wherein the plurality of via caps are flush with the substrate core such that no part of individual via caps of the plurality of via caps extends above the plane defined by the top side of the substrate core.

Example 15 includes the subject matter of any of Examples 11-14, and wherein individual via caps of the plurality of via caps are anchored to the top side of the substrate core.

Example 16 includes the subject matter of any of Examples 11-15, and wherein individual via caps of the plurality of via caps comprise a seed layer with a first grain structure and an electroplated layer with a second grain structure different from the first grain structure.

Example 17 includes the subject matter of any of Examples 11-16, and wherein individual via caps of the plurality of via caps are not anchored to the substrate core.

Example 18 includes the subject matter of any of Examples 11-17, and wherein cross-sections of individual vias of the plurality of vias taken perpendicular to the individual vias do not contact the sidewalls of the corresponding cavity of the plurality of cavities.

Example 19 includes the subject matter of any of Examples 11-18, and wherein, for individual cavities of the plurality of cavities, a liner is disposed around an outside perimeter of the corresponding cavity, wherein the sidewalls of the plurality of cavities are the sidewalls of the corresponding liner.

Example 20 includes the subject matter of any of Examples 11-19, and wherein less than half of a surface area of individual vias of the plurality of vias is in contact with sidewalls of the corresponding cavity of the plurality of cavities.

Example 21 includes the subject matter of any of Examples 11-20, and further including a plurality of build-up layers adjacent the top side and the bottom side; and one or more semiconductor dies mounted on a build-up layer of the plurality of build-up layers.

Example 22 includes a method comprising creating a plurality of holes in a glass core; and creating a plurality of vias with via caps in the plurality of holes using bottom-up plating.

Example 23 includes the subject matter of Example 22, and wherein creating the plurality of vias with via caps in the plurality of holes comprises forming a seed layer on the glass core; patterning photoresist on the seed layer; electroplating the via caps for the plurality of vias on the seed layer in regions defined by the photoresist; and electroplating the plurality of vias on the via caps.

Example 24 includes the subject matter of any of Examples 22 and 23, and wherein creating the plurality of vias with via caps in the plurality of holes comprises patterning photoresist on the glass core; bonding a carrier on the glass core, wherein the carrier comprises a seed layer; electroplating the via caps for the plurality of vias on the seed layer in regions defined by the photoresist; and electroplating the plurality of vias on the via caps.

Example 25 includes the subject matter of any of Examples 22-24, and wherein creating the plurality of vias with via caps in the plurality of holes comprises creating a plurality of countersunk holes around the plurality of holes in the glass core; forming a seed layer on the glass core; patterning photoresist on the seed layer; electroplating the via caps for the plurality of vias on the seed layer in regions defined by the photoresist; and electroplating the plurality of vias on the via caps.

1. An apparatus comprising:
a substrate core, the substrate core comprising a top side and a bottom side, wherein a plurality of cavities are defined within the substrate core, wherein individual cavities of the plurality of cavities extend from the bottom side to the top side;
a plurality of vias extending through the plurality of cavities defined in the substrate core, wherein individual vias of the plurality of vias are not anchored to sidewalls of a corresponding cavity of the plurality of cavities; and
a plurality of via caps, wherein individual via caps of the plurality of via caps are disposed at one end of individual vias of the plurality of vias.

2. The apparatus of claim 1, wherein the plurality of via caps are countersunk in the substrate core such that at least part of individual via caps of the plurality of via caps extends below a plane defined by the top side of the substrate core.

3. The apparatus of claim 2, wherein the plurality of via caps are flush with the substrate core such that no part of individual via caps of the plurality of via caps extends above the plane defined by the top side of the substrate core.

4. The apparatus of claim 1, wherein individual via caps of the plurality of via caps are anchored to the top side of the substrate core.

5. The apparatus of claim 4, wherein individual via caps of the plurality of via caps comprise a seed layer with a first grain structure and an electroplated layer with a second grain structure different from the first grain structure.

6. The apparatus of claim 1, wherein a gap of at least 10 nanometers is present between at least part of individual vias of the plurality of vias and sidewalls of the corresponding cavity of the plurality of cavities.

7. The apparatus of claim 1, wherein cross-sections of individual vias of the plurality of vias taken perpendicular to the individual vias do not contact the sidewalls of the corresponding cavity of the plurality of cavities.

8. The apparatus of claim 1, further comprising:
a plurality of build-up layers adjacent the top side and the bottom side; and
one or more semiconductor dies mounted on a build-up layer of the plurality of build-up layers.

9. An apparatus comprising:
a substrate core, the substrate core comprising a top side and a bottom side, wherein a plurality of cavities are defined within the substrate core extending from the bottom side to the top side;
a plurality of vias extending through the plurality of cavities defined in the substrate core, wherein a gap of at least 10 nanometers is present between at least part of individual vias of the plurality of vias and sidewalls of a corresponding cavity of the plurality of cavities; and
a plurality of via caps, wherein individual via caps of the plurality of via caps are disposed at one end of individual vias of the plurality of vias.

10. The apparatus of claim 9, wherein individual vias of the plurality of vias are not anchored to sidewalls of the corresponding cavity of the plurality of cavities.

11. The apparatus of claim 9, wherein the plurality of via caps are countersunk in the substrate core such that at least part of individual via caps of the plurality of via caps extends below a plane defined by the top side of the substrate core.

12. The apparatus of claim 9, wherein individual via caps of the plurality of via caps are anchored to the top side of the substrate core.

13. The apparatus of claim 12, wherein individual via caps of the plurality of via caps comprise a seed layer with a first grain structure and an electroplated layer with a second grain structure different from the first grain structure.

14. The apparatus of claim 9, wherein individual via caps of the plurality of via caps are not anchored to the substrate core.

15. The apparatus of claim 9, wherein, for individual cavities of the plurality of cavities, a liner is disposed around an outside perimeter of the corresponding cavity, wherein the sidewalls of the plurality of cavities are the sidewalls of the corresponding liner.

16. The apparatus of claim 9, wherein less than half of a surface area of individual vias of the plurality of vias is in contact with sidewalls of the corresponding cavity of the plurality of cavities.

17. The apparatus of claim 9, further comprising:
a plurality of build-up layers adjacent the top side and the bottom side; and
one or more semiconductor dies mounted on a build-up layer of the plurality of build-up layers.

18. A method comprising:
creating a plurality of holes in a glass core; and
creating a plurality of vias with via caps in the plurality of holes using bottom-up plating.

19. The method of claim 18, wherein creating the plurality of vias with via caps in the plurality of holes comprises:
forming a seed layer on the glass core;
patterning photoresist on the seed layer;
electroplating the via caps for the plurality of vias on the seed layer in regions defined by the photoresist; and
electroplating the plurality of vias on the via caps.

20. The method of claim 18, wherein creating the plurality of vias with via caps in the plurality of holes comprises:
patterning photoresist on the glass core;
bonding a carrier on the glass core, wherein the carrier comprises a seed layer;
electroplating the via caps for the plurality of vias on the seed layer in regions defined by the photoresist; and
electroplating the plurality of vias on the via caps.
